(19) United States
(12) Patent Application Publication
(10) Pub. No.: US 2025/0057034 A1
(43) Pub. Date: Feb. 13, 2025

(54) METAL COMPLEX AND ORGANIC LIGHT-EMITTING DEVICE

(71) Applicant: CANON KABUSHIKI KAISHA, Tokyo (JP)

(72) Inventors: AKIRA TSUBOYAMA, Tokyo (JP); AKANE TANAKA, Kanagawa (JP)

(21) Appl. No.: 18/930,227

(22) Filed: Oct. 29, 2024

Related U.S. Application Data
(63) Continuation of application No. PCT/JP2023/014596, filed on Apr. 10, 2023.

(30) Foreign Application Priority Data
May 2, 2022 (JP) 2022-075870

(51) Int. Cl. H10K 85/30; C07F 15/00; C09K 11/06; H10K 50/12

(52) U.S. Cl. CPC H10K 85/346; C07F 15/0086; C09K 11/06; C09K 2211/1029; C09K 2211/1088; C09K 2211/185; H10K 50/12

(57) ABSTRACT

The present disclosure provides a metal complex that can achieve both productivity in the production of an organic light-emitting device and high emission characteristics, the metal complex being represented by general formula (1) below.

M represents Pt, Pd, or Ni. R₁ to R₁₀ are each independently selected from a hydrogen atom and an alkyl group, provided that at least one of R₁ to R₁₀ is an alkyl group having 2 or more carbon atoms. —X—Y— represents a bidentate ligand and is —O—O—, —N—O—, —C—N—, or —N—N—.

### CROSS-REFERENCE TO RELATED APPLICATIONS

This application is a Continuation of International Patent Application No. PCT/JP2023/014596, filed Apr. 10, 2023, which claims the benefit of Japanese Patent Application No. 2022-075870, filed May 2, 2022, both of which are hereby incorporated by reference herein in their entirety.

### TECHNICAL FIELD

The present invention relates to a metal complex and an organic light-emitting device.

### BACKGROUND ART

An organic light-emitting device is an electronic device including a first electrode, a second electrode, and an organic compound layer disposed between the electrodes. The injection of electrons and holes from this pair of electrodes generates excitons of a light-emitting organic compound in the organic compound layer, and the organic light-emitting device emits light when the excitons return to the ground state. Organic light-emitting devices are also referred to as organic electroluminescent devices or organic EL devices.

Light-emitting materials used for light-emitting compounds can be broadly classified into two types of materials on the basis of their luminescence principle: fluorescent materials and phosphorescent materials. In organic EL devices, phosphorescent materials, which emit light from the triplet excited state, are known to exhibit higher emission quantum yields than fluorescent materials, which emit light from the singlet excited state. As an example thereof, NPL 1 describes, as a green phosphorescent material, a metal complex Ir(ppy)₃ represented by the following structure.

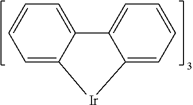

It has been reported that an organic EL device including 4,4′-di(N-carbazolyl)biphenyl (CBP) doped with the metal complex Ir(ppy)₃ emits green light having an emission wavelength of 510 nm and has an external quantum efficiency of 13%, which is significantly higher than a quantum efficiency limit value (5%) of an existing light-emitting device utilizing light emission from the singlet excited state.

In addition to Ir complexes, metal complexes with central metals such as platinum (Pt) are being actively developed as phosphorescent materials. PTL 1 and NPL 2 disclose Pt complex phosphorescent materials. Specifically, PTL 1 discloses, for example, Pt complexes having a dibenzofuran moiety. NPL 2 similarly discloses Pt complexes having a dibenzofuran moiety with a substituent such as a CH₃ group or a CF₃ group.

### CITATION LIST

### Patent Literature

PTL 1 Japanese Patent Laid-Open No. 2002-332291

### Non Patent Literature

NPL 1 Appl. Phys. Lett., vol. 75, p. 4, 1999
NPL 2 Dyes and Pigments, Volume 124, 2016, Pages 165-173

Use of a ligand having a dibenzofuran skeleton for a Pt complex can achieve stable and good emission characteristics. However, NPL 2 has reported PL emission characteristics and EL emission characteristics of Pt complexes having a dibenzofuran skeleton in detail, and technical problems have become apparent when such Pt complexes are used in organic EL devices. Specifically, unlike Ir complexes having a three-dimensional structure of a six-coordinated octahedral structure, Pt complexes have a four-coordinated planar structure, and thus intermolecular interaction is likely to occur between Pt complexes. Ligands of phosphorescent Pt complexes have abundant n-orbital electrons, and a relatively strong interaction between π-electrons is observed. Referring to emission spectra of a Pt complex in NPL 2, the intermolecular interaction is clearly visible in the emission characteristics. Specifically, it is disclosed that as the concentration of the Pt complex in a thin film (PMMA) increases, excimer emission appears broadly on the longer wavelength side than the original emission peak wavelength of the Pt complex.

A description will be given in more detail using the following Pt complex compounds described in NPL 2 as Comparative example compounds.

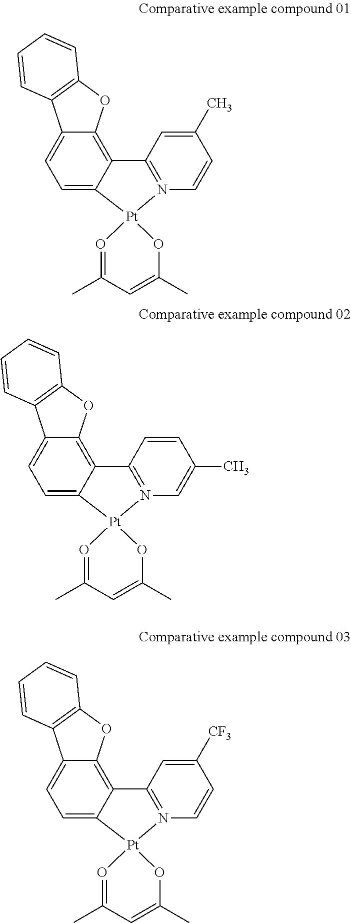

NPL 2 describes excimer emission when a comparative example compound is used as a light-emitting dopant in a thin film. With regard to Comparative example compound 01, when the light-emitting dopant concentration of a light-emitting layer in an organic EL device is 13% or more, in addition to the original emission spectrum peak (524 nm) of the Pt complex, a broad, intense emission peak (around 600 nm) is observed. This phenomenon is also observed in PL emission caused by photoexcitation.

In general, it is said that excimer emission occurs when light-emitting dopants undergo intermolecular interactions in the excited state, and is likely to occur when (a) the concentration of the light-emitting dopant is high and (b) the light-emitting dopant is a planar molecule. Since the light emission can be broadened by excimer emission, an application to white light emission is expected. On the other hand, since the emission spectrum changes depending on the light-emitting dopant concentration, for example, there are the following technical problems:
(1) A color change due to a variation in the concentration occurs, and, regarding an organic EL device formed from pixels of RGB three primary colors, the production margin due to the variation in the concentration is narrow.
(2) When an organic EL device is designed, it is necessary to reduce undesirable excimer emission that degrades the color purity of a single color, and the light-emitting dopant concentration is limited, which affects the design of other organic EL layers.

### SUMMARY OF INVENTION

The present invention has been made in view of the above problems. An object of the present invention is to provide a metal complex that can achieve both productivity in the production of an organic light-emitting device and high emission characteristics.

A metal complex according to the present invention is represented by general formula (1) below.

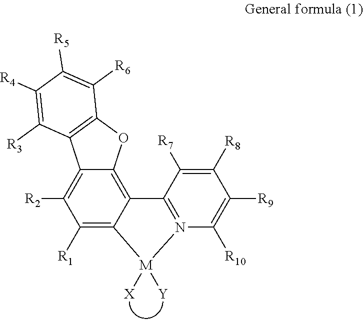

In general formula (1), M represents Pt, Pd, or Ni.

R₁ to R₁₀ are each independently selected from a hydrogen atom and an alkyl group, provided that at least one of R₁ to R₁₀ is an alkyl group having 2 or more carbon atoms. Adjacent R₁ to R₁₀ may be bonded together to form a ring. —X—Y— represents a bidentate ligand and is —O—O—, —N—O—, —C—N—, or —N—N—.

Further features of the present invention will become apparent from the following description of exemplary embodiments with reference to the attached drawings.

### BRIEF DESCRIPTION OF DRAWINGS

FIG. 1A is a schematic sectional view illustrating an example of pixels of a display apparatus according to an embodiment of the present invention.

FIG. 1B is a schematic sectional view illustrating an example a display apparatus using an organic light-emitting device according to an embodiment of the present invention.

FIG. 2 is a schematic view illustrating an example of a display apparatus according to an embodiment of the present invention.

FIG. 3A is a schematic view illustrating an example of an imaging apparatus according to an embodiment of the present invention.

FIG. 3B is a schematic view illustrating an example of an electronic apparatus according to an embodiment of the present invention.

FIG. 4A is a schematic view illustrating an example of a display apparatus according to an embodiment of the present invention.

FIG. 4B is a schematic view illustrating an example of a foldable display apparatus.

FIG. 5A is a schematic view illustrating an example of an illumination apparatus according to an embodiment of the present invention.

FIG. 5B is a schematic view illustrating an example of a moving object including a vehicle lighting fixture according to an embodiment of the present invention.

FIG. 6A is a schematic view illustrating an example of a wearable device according to an embodiment of the present invention.

FIG. 6B is a schematic view illustrating another example of the wearable device according to an embodiment of the present invention.

FIG. 7A is a schematic diagram illustrating an example of an image forming apparatus according to an embodiment of the present invention.

FIG. 7B is a schematic view illustrating an example of an exposure light source for an image forming apparatus according to an embodiment of the present invention.

FIG. 7C is a schematic view illustrating an example of an exposure light source for an image forming apparatus according to an embodiment of the present invention.

FIG. 8 is an emission spectrum of Example compound 03.

FIG. 9A is an NMR spectrum of Example compound 03.

FIG. 9B is an NMR spectrum of Example compound 03.

### DESCRIPTION OF EMBODIMENTS

Embodiments of the present invention will be described below. The present invention is not limited by the description below, and a person skilled in the art could easily recognize that various changes in the forms and details can be made without departing from the spirit and the scope of the present invention. That is, the present invention should not be construed as being limited to the following description.

### Metal Complex

As described above, Pt, Pd, and Ni complexes with high planarity have a problem in that when used in a light-emitting layer at a high concentration, excimer emission is likely to occur, and the emission color changes depending on the concentration. The inventors of the present invention have conducted extensive studies to address this problem and found an organometallic complex represented by general formula (1) below, the organometallic complex exhibiting an emission spectrum that is independent of the concentration.

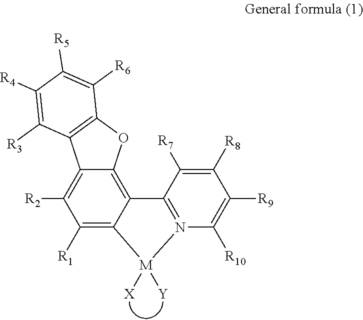

### M

In general formula (1), M is a metal atom and represents Pt, Pd, or Ni. M is preferably Pt.

R₁ to R₁₀

In general formula (1), R₁ to R₁₀ are each independently selected from a hydrogen atom and an alkyl group. However, at least one of R₁ to R₁₀, preferably at least one of R₈ and R₉ is an alkyl group having 2 or more carbon atoms.

The alkyl group may be linear, branched, or cyclic. Examples of the alkyl group include, but are not limited to, a methyl group, an ethyl group, a normal propyl group, an isopropyl group, a normal butyl group, a tertiary butyl group, a secondary butyl group, an octyl group, a cyclohexyl group, a 1-adamantyl group, and a 2-adamantyl group. Of these, alkyl groups having 1 to 10 carbon atoms are preferred.

Adjacent R₁ to R₁₀, preferably adjacent R₁ and R₂, adjacent R₃ to R₆, or adjacent R₇ to R₁₀ may be bonded together to form a ring. The expression “adjacent R₁ to R₁₀ are bonded together to form a ring” means that, for example, a ring formed by bonding R₁ and R₂ together and the benzene ring to which R₁ and R₂ are bonded form a fused ring, a ring formed by bonding R₃ and R₄, R₄ and R₅, or R₅ and R₆ together and the benzene ring to which R₃ to R₆ are bonded form a fused ring, or a ring formed by bonding R₇ and R₈, R₈ and R₉, or R₉ and R₁₀ together and the pyridine ring to which R₇ to R₁₀ are bonded form a fused ring. The ring formed may be an alicyclic ring or an aromatic ring. —X—Y—

In general formula (1), —X—Y— represents a bidentate ligand and is —O—O—, —N—O—, —C—N—, or —N—N—. X and Y in —X—Y— are bonded to each other via an atomic group constituting the bidentate ligand together with X and Y. —X—Y— is preferably a ligand other than a ligand having a dibenzofuran-pyridine skeleton and is preferably an acetylacetonate derivative.

A metal complex of the present embodiment is preferably a metal complex represented by general formula (2) below.

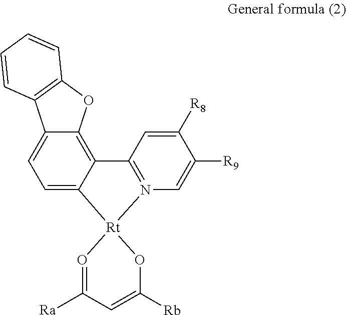

### Ra and Rb

In general formula (2), Ra and Rb are each independently selected from an alkyl group and a substituted or unsubstituted aromatic ring group.

The alkyl group may be linear, branched, or cyclic. Examples of the alkyl group include, but are not limited to, a methyl group, an ethyl group, a normal propyl group, an isopropyl group, a normal butyl group, a tertiary butyl group, a secondary butyl group, an octyl group, a cyclohexyl group, a 1-adamantyl group, and a 2-adamantyl group. Of these, alkyl groups having 1 to 10 carbon atoms are preferred.

The aromatic ring group may be an aromatic hydrocarbon group or a heteroaromatic compound group. The aromatic ring group is preferably an aromatic hydrocarbon group.

Examples of the aromatic hydrocarbon group include, but are not limited to, a phenyl group, a naphthyl group, an indenyl group, a biphenyl group, a terphenyl group, a fluorenyl group, a phenanthryl group, and a triphenylenyl group. Of these, aromatic hydrocarbon groups having 6 to 18 carbon atoms are preferred.

Examples of the heteroaromatic compound group include, but are not limited to, a pyridyl group, a pyrazinyl group, a pyrimidinyl group, a triazinyl group, a quinolyl group, an isoquinolyl group, an oxazolyl group, a thiazolyl group, an imidazolyl group, a benzoxazolyl group, a benzothiazolyl group, a benzimidazolyl group, a thienyl group, a furanyl group, a pyronyl group, a benzothienyl group, a benzofuranyl group, an indonyl group, a dibenzothiophenyl group, and a dibenzofuranyl group. Of these, heteroaromatic compound groups having 3 to 15 carbon atoms are preferred.

Examples of substituents that the aromatic ring group may have include, but are not limited to, alkyl groups such as a methyl group, an ethyl group, a normal propyl group, an isopropyl group, a normal butyl group, and a tertiary butyl group; aralkyl groups such as a benzyl group; aryl groups such as a phenyl group and a biphenyl group; amino groups such as a dimethylamino group, a diethylamino group, a dibenzylamino group, a diphenylamino group, and a ditolylamino group; alkoxy groups such as a methoxy group, an ethoxy group, and propoxy group; aryloxy groups such as a phenoxy group; halogen atoms such as fluorine, chlorine, bromine, and iodine; and a thienyl group, a thiol group, and a cyano group.

### Specific Examples of Ligand Having Dibenzofuran-Pyridine Skeleton

In general formula (1), the ligand having a dibenzofuran-pyridine skeleton is a light-emitting ligand. Examples of the light-emitting ligand include, but are not limited to, ligands shown below. These ligands have a dibenzofuran-pyridine skeleton with a developed conjugated system so as to achieve visible light emission. The synthesis of a metal complex using a ligand having this skeleton provides good emission characteristics. The basic emission color is green to yellow-green light emission.

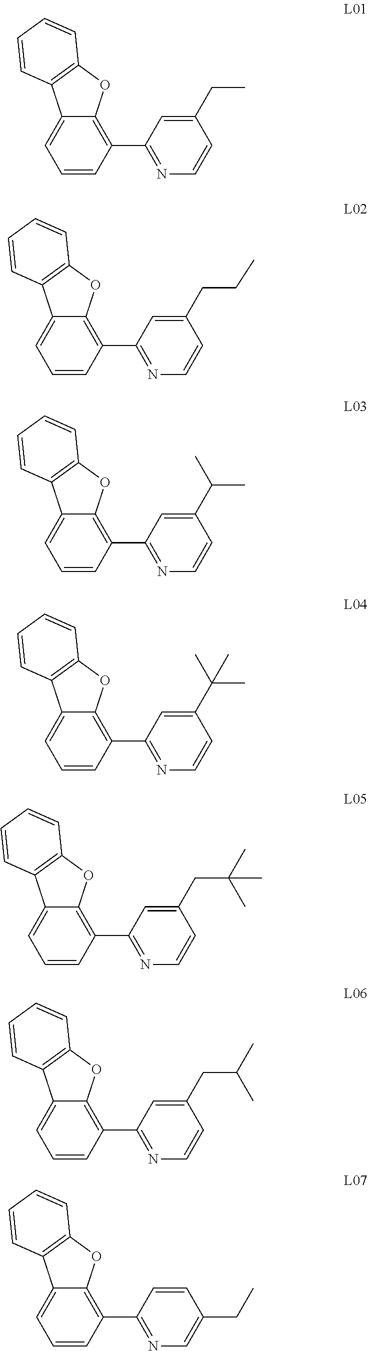

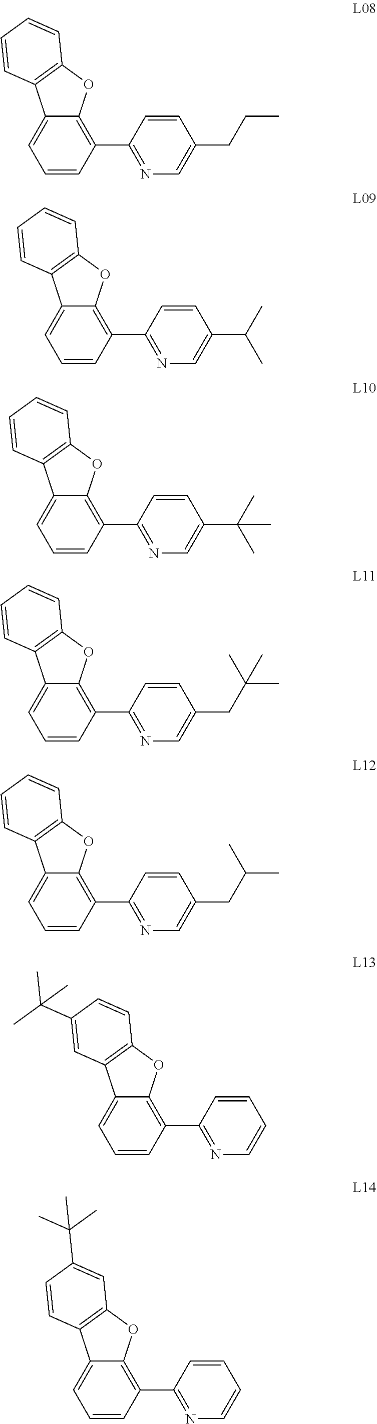

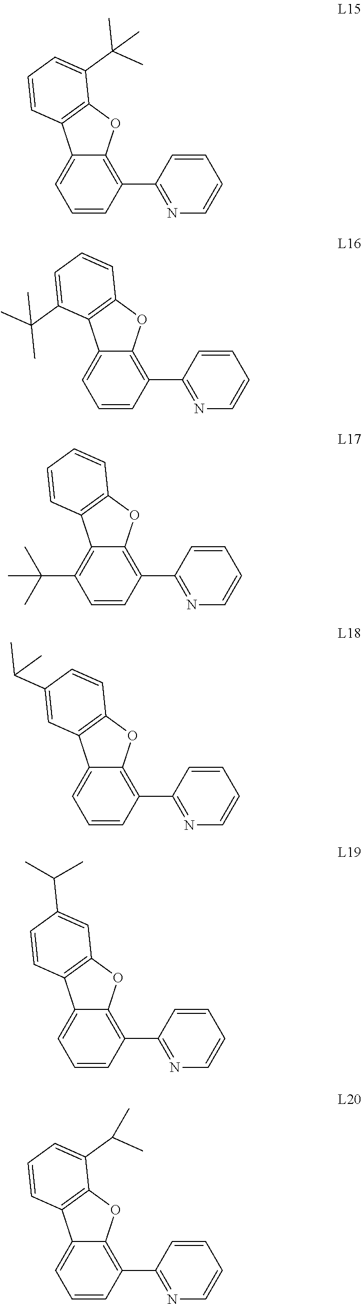

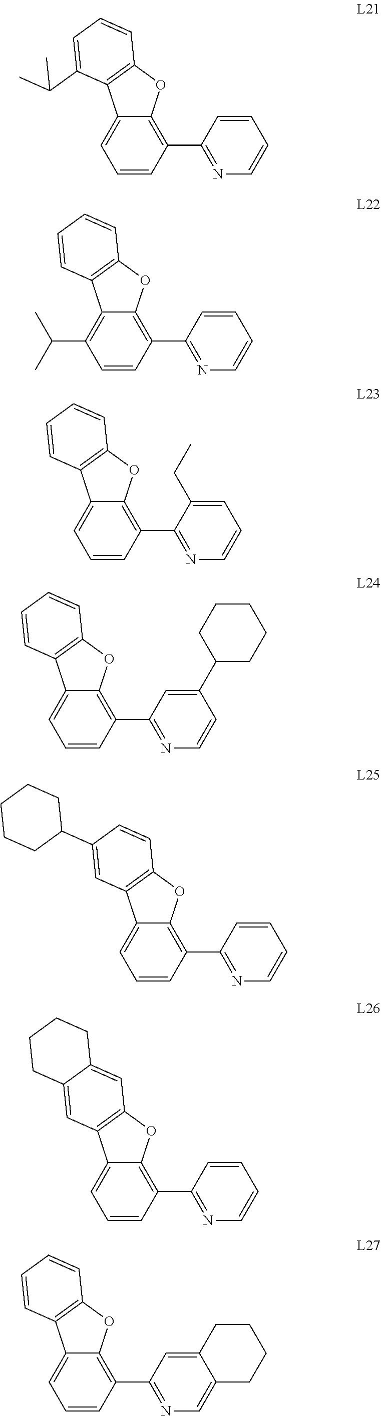

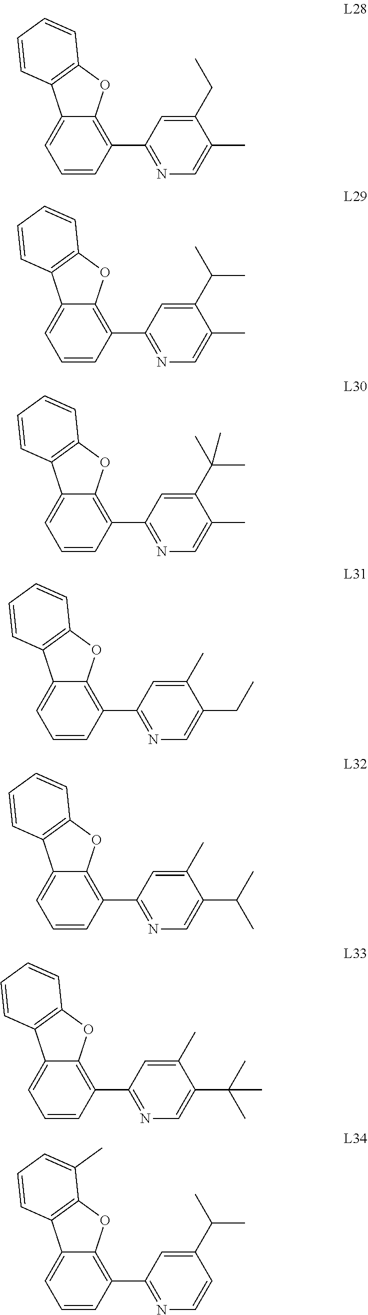

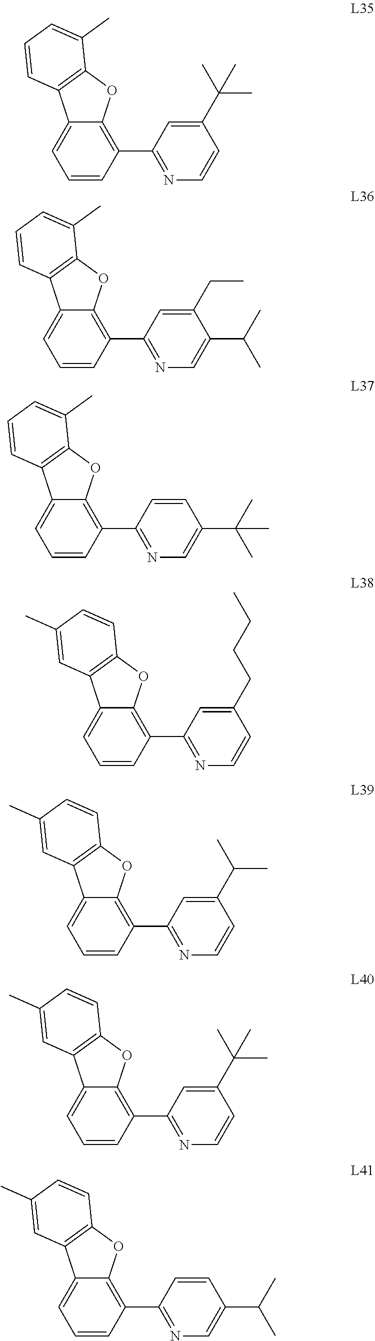

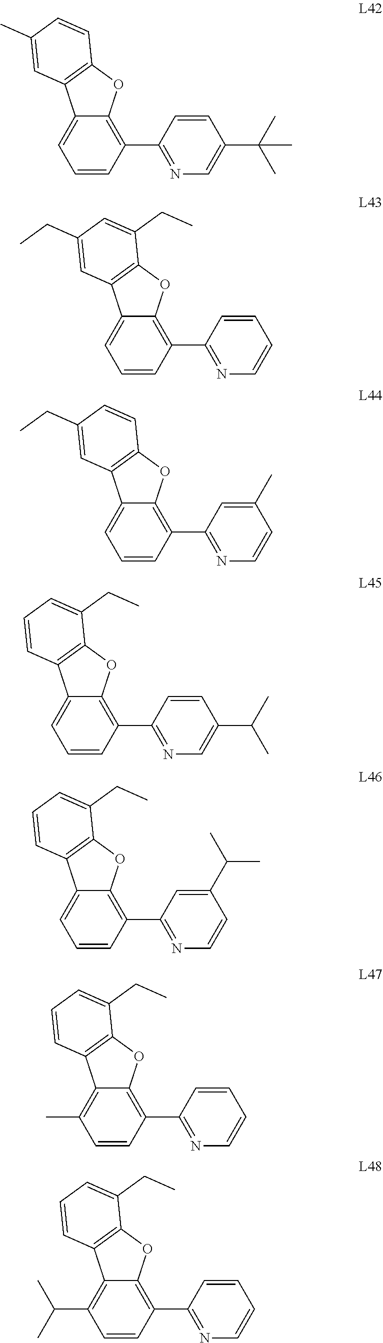

### Specific Examples of Bidentate Ligand Represented by —X—Y—

In general formula (1), the bidentate ligand represented by —X—Y— is an auxiliary ligand. Examples of the auxiliary ligand include, but are not limited to, ligands shown below. The auxiliary ligand is important in finely adjusting emission characteristics and controlling stability.

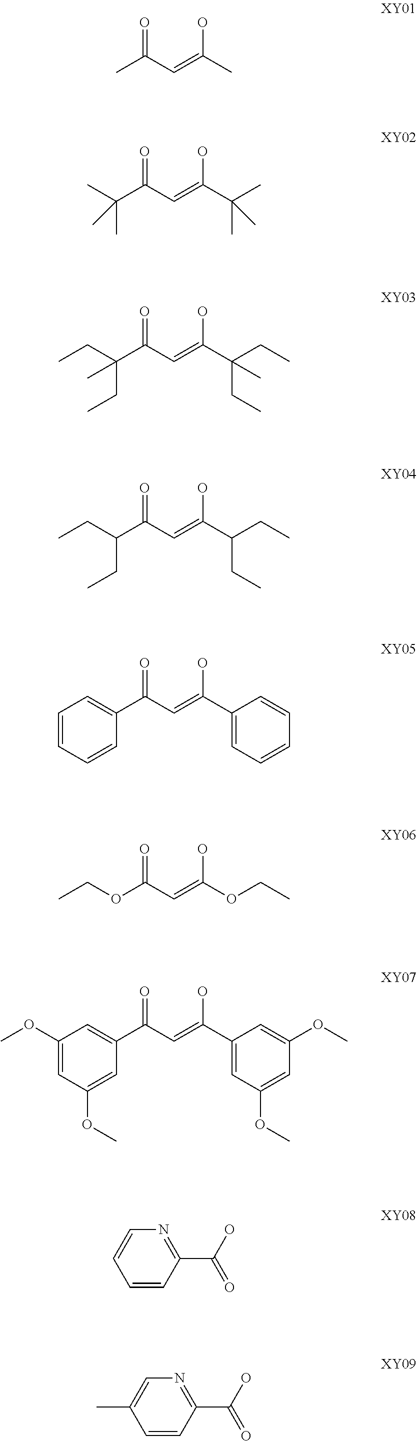

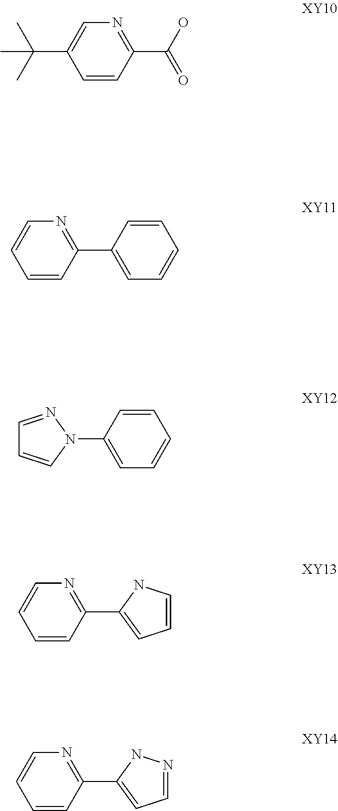

### Exemplary Compound

The metal complex of the present embodiment can be formed by combining, for example, a light-emitting ligand selected from L01 to L48 and an auxiliary ligand selected from XY01 to XY14. Examples of the metal complex of the present embodiment are shown below, but of course, the metal complex is not limited thereto.

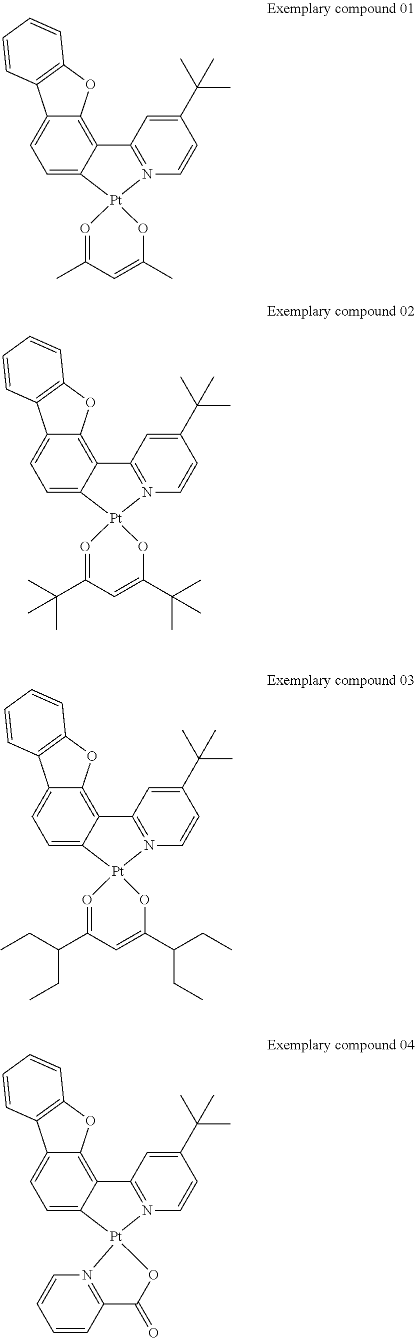

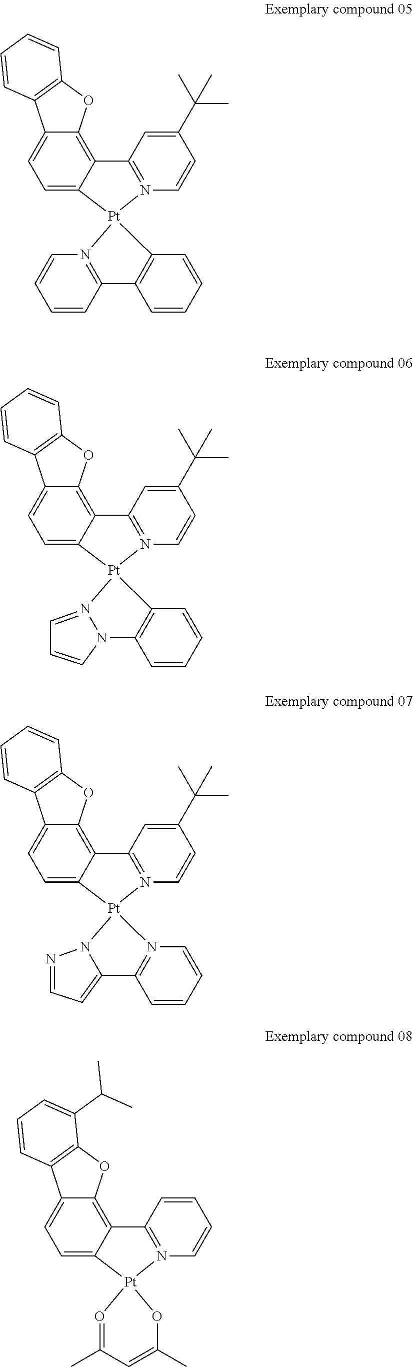

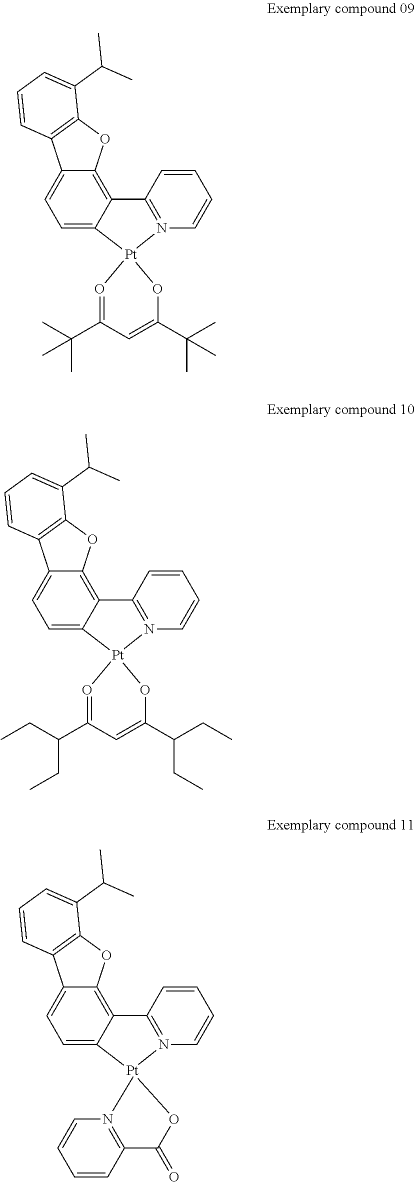

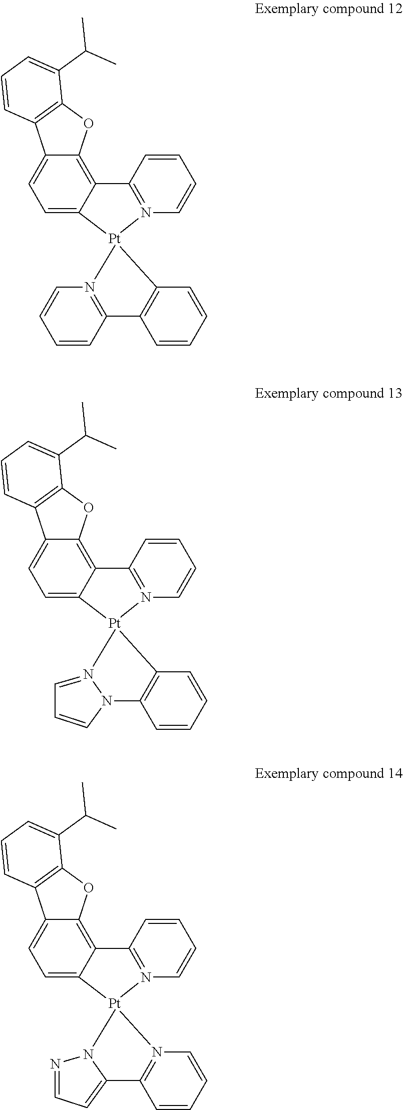

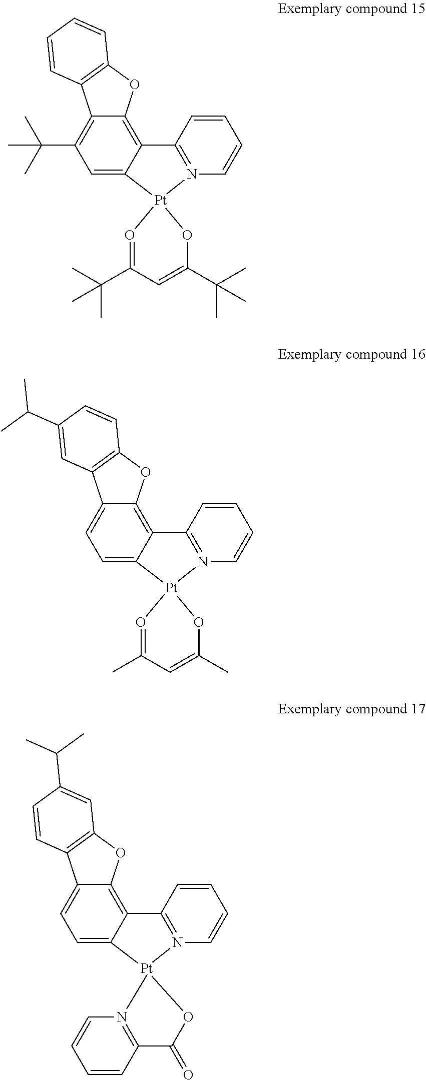

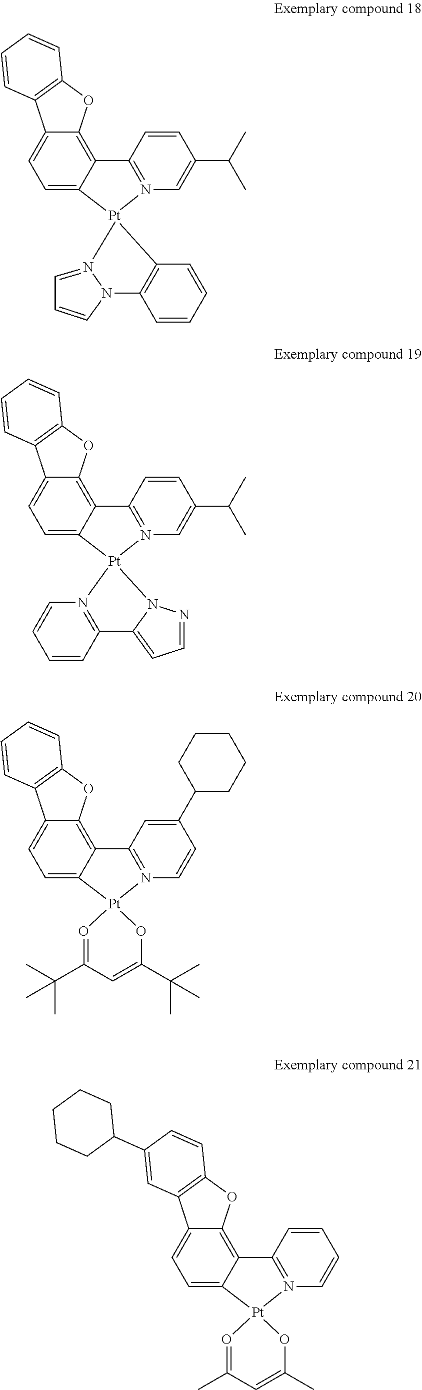

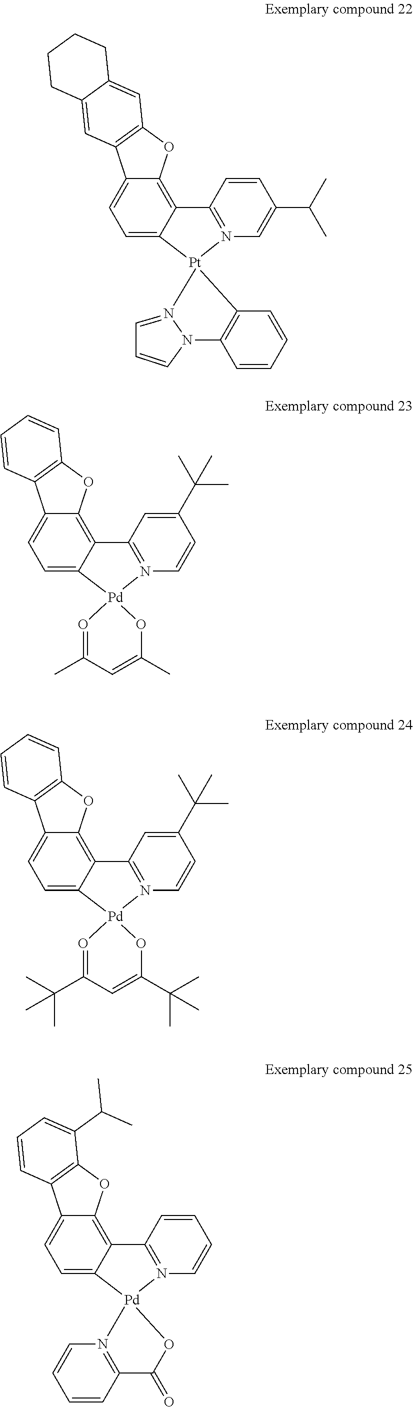

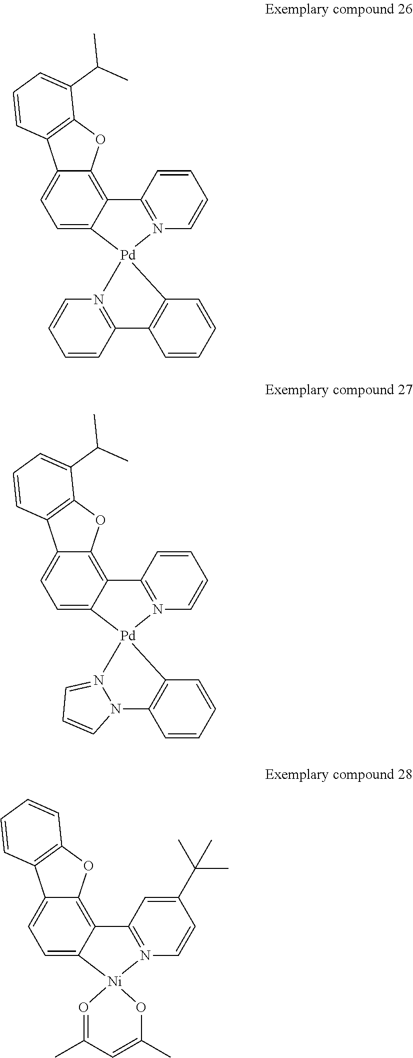

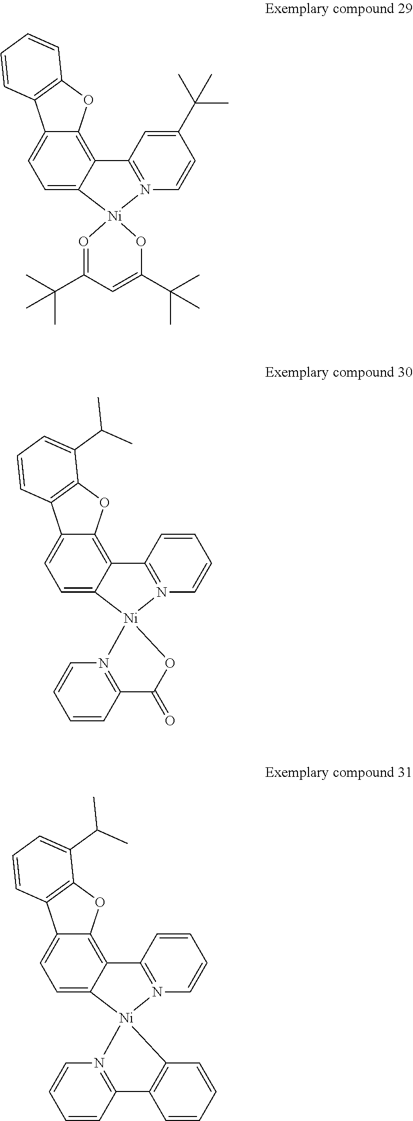

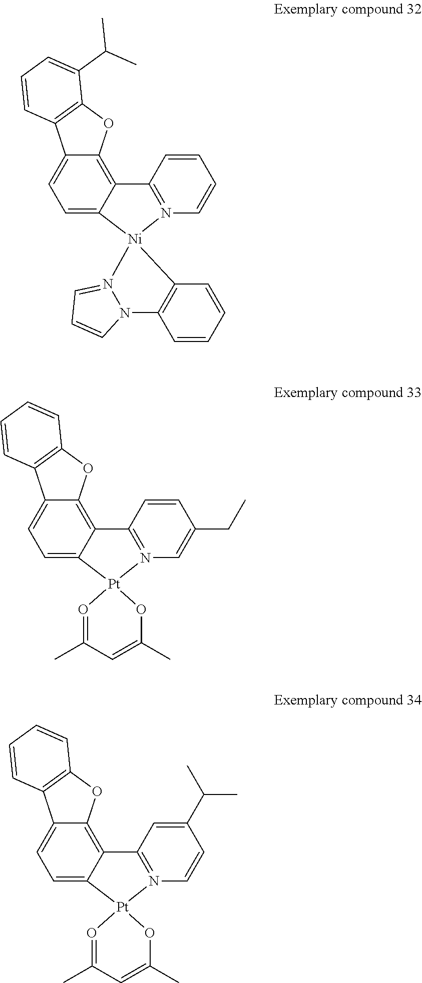

### Characteristics of Emission Spectrum

Characteristics of an emission spectrum in the metal complex of the present embodiment will be described. The central metal of the metal complex of the present embodiment is Pt(II), Pd(II), or Ni(II), and the metal complex is a d8 complex having eight d electrons. Such a d8 complex usually has a four-coordinated planar structure. Two bidentate ligands are used as ligands that forms the four-coordinated planar structure. As described above, one is a light-emitting ligand that determines emission characteristics, and the other is an auxiliary ligand.

A light-emitting metal complex is often used after being dispersed in a host material of a light-emitting layer. A light-emitting dopant concentration of a light-emitting material in the light-emitting layer included in an organic EL device is designed so that good emission characteristics can be maintained. If emission characteristics (such as an emission spectrum and emission quantum yield) change greatly depending on the light-emitting dopant concentration, an allowable range of variation in the light-emitting dopant concentration decreases. This results in limitations on productivity of an organic EL device and the device design.

In a metal complex having a four-coordinated planar structure and having a developed conjugated system, in general, intermolecular interaction is likely to occur. An increase in the dopant concentration in the light-emitting layer causes a technical problem, such as the appearance of excimer emission, resulting in a change in the emission spectrum. Excimer emission is a light emission phenomenon that appears as a result of intermolecular interaction between light-emitting dopants, and occurs when a light-emitting exciton interacts with another light-emitting dopant molecule.

As a result of studies conducted by the inventors of the present invention, it has been found that, for this technical problem, the intermolecular interaction can be suppressed by the substituent effect of a light-emitting ligand and that it is possible to provide a metal complex light-emitting material in which excimer emission can be sufficiently suppressed even in a case of a high dopant concentration.

### Organic Light-Emitting Device

An organic light-emitting device according to the present embodiment includes at least a first electrode and a second electrode, which are a pair of electrodes, and an organic compound layer disposed between the electrodes. In the organic light-emitting device of the present embodiment, the organic compound layer may be a single layer or a stack of a plurality of layers as long as the organic compound layer includes a light-emitting layer. The pair of electrodes may be an anode and a cathode.

When the organic compound layer is a stack of a plurality of layers, the organic compound layer may include a light-emitting layer. The organic compound layer may include, besides the light-emitting layer, for example, a hole injection layer, a hole transport layer, an electron-blocking layer, a hole/exciton-blocking layer, an electron transport layer, and an electron injection layer. The light-emitting layer may be a single layer or a stack of a plurality of layers. The hole transport layer and the electron transport layer are also referred to as charge transport layers.

In the organic light-emitting device of the present embodiment, the organometallic complex according to the present embodiment is contained in at least one layer in the organic compound layer. Specifically, the organometallic complex according to the present embodiment is contained in any of the hole injection layer, the hole transport layer, the electron-blocking layer, the light-emitting layer, the hole/exciton-blocking layer, the electron transport layer, the electron injection layer, and the like and is preferably contained in the light-emitting layer. The transport layers between the first electrode and the light-emitting layer can be collectively referred to as a first charge transport layer. The transport layers between the second electrode and the light-emitting layer can be collectively referred to as a second charge transport layer. That is, the light-emitting layer is in contact with the first charge transport layer and in contact with the second charge transport layer.

In the organic light-emitting device of the present embodiment, when the organometallic complex according to the present embodiment is contained in a light-emitting layer, the light-emitting layer may be a layer composed only of the organometallic complex according to the present embodiment or a layer that contains, in addition to the organometallic complex according to the present embodiment, a first organic compound and a second organic compound different from the first organic compound. The first organic compound may have a higher lowest excited triplet energy than the lowest excited triplet energy of the organometallic complex of the present embodiment. The lowest excited triplet energy of the second organic compound may be equal to or higher than the lowest excited triplet energy of the organometallic complex of the present embodiment and equal to or lower than the lowest excited triplet energy of the first organic compound. When the light-emitting layer is a layer containing the first organic compound and the second organic compound, the first organic compound may be a host of the light-emitting layer. The second organic compound may be an assist material. The organometallic complex according to the present embodiment may be a guest or a dopant.

Herein, the host refers to, among the compounds that form the light-emitting layer, a compound having the highest mass proportion. The guest or dopant refers to, among the compounds that form the light-emitting layer, a compound that has a lower mass proportion than the host and that is responsible for main light emission. The assist material refers to, among the compounds that form the light-emitting layer, a compound that has a lower mass proportion than the host and that assists light emission of the guest. The assist material is also referred to as a second host.

When the organometallic complex according to the present embodiment is used as the guest of the light-emitting layer, the concentration of the guest is preferably 0.01% by mass or more and 20% by mass or less, more preferably 0.1% by mass or more and 10.0% by mass or less, based on the entire light-emitting layer. The entire light-emitting layer refers to the total mass of the compounds that form the light-emitting layer.

The lowest excited triplet energy of the first charge transport layer is preferably higher than the lowest excited triplet energy of the first organic compound. The lowest excited triplet energy of the second charge transport layer is preferably higher than the lowest excited triplet energy of the first organic compound. The lowest excited triplet energy of the charge transport layer can be estimated by the lowest excited triplet energy of the constituent material of the layer. When the charge transport layer is composed of a plurality of materials, the lowest excited triplet energy may be the lowest excited triplet energy of a compound having a high mass proportion.

The inventors have conducted various studies and have found that when the organometallic complex according to the present embodiment is used as a guest of a light-emitting layer, light output with high efficiency and high luminance is exhibited, and good roll-off characteristics are provided. This light-emitting layer may be formed of a single layer or multiple layers and can also contain a light-emitting material having another emission color to thereby form a color mixture of the emission color of the present embodiment and the other emission color. The “multiple layers” means a state in which a plurality of light-emitting layers are stacked. In this case, the emission color of the organic light-emitting device is not limited to the same hue as the emission color of the single layer. More specifically, the emission color may be white or a neutral color. In the case of white, red light, blue light, and green light may be emitted from the light-emitting layers to obtain white light, or complementary emission colors may be combined to obtain white light.

The organometallic complex according to the present embodiment can be used as a constituent material of an organic compound layer other than the light-emitting layer included in the organic light-emitting device of the present embodiment. Specifically, the organometallic complex may be used as a constituent material of the electron transport layer, the electron injection layer, the hole transport layer, the hole injection layer, the hole-blocking layer, or the like.

### Other Compounds

In producing the organic light-emitting device according to the present embodiment, publicly known low-molecular-weight and high-molecular-weight hole injection compounds or hole transport compounds, compounds serving as the host, light-emitting compounds, and electron injection compounds or electron transport compounds can be used in combination as necessary. Examples of these compounds will be described below.

The hole injection/transport material is preferably a material having a high hole mobility so as to facilitate hole injection from the anode and to enable the injected holes to be transported to the light-emitting layer. The hole injection/transport material is preferably a material having a high glass transition temperature in order to reduce degradation of the film quality, such as crystallization, in the organic light-emitting device. Examples of the low-molecular-weight and high-molecular-weight materials having a hole injection/transport property include triarylamine derivatives, arylcarbazole derivatives, phenylenediamine derivatives, triazole derivatives, oxadiazole derivatives, imidazole derivatives, stilbene derivatives, phthalocyanine derivatives, porphyrin derivatives, conductive polymers such as polyarylamine derivatives, polyvinylcarbazole derivatives, polythiophene derivatives, and PEDOT-PSS, copolymers thereof, and mixtures thereof. The above hole injection/transport materials are also suitable for use in an electron-blocking layer. Specific examples of the compound used as the hole injection/transport material are shown below, but of course, the hole injection/transport material is not limited thereto.

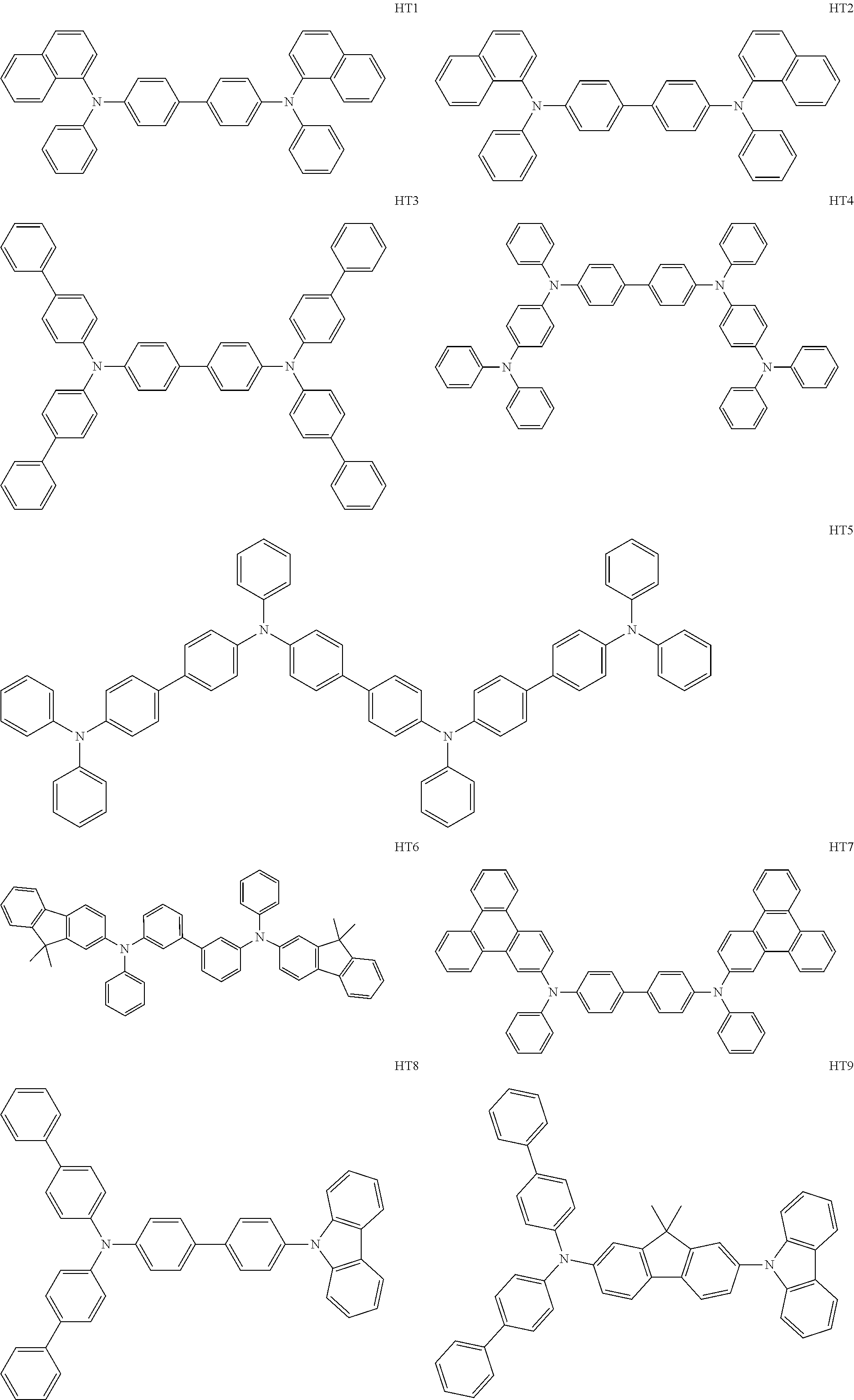

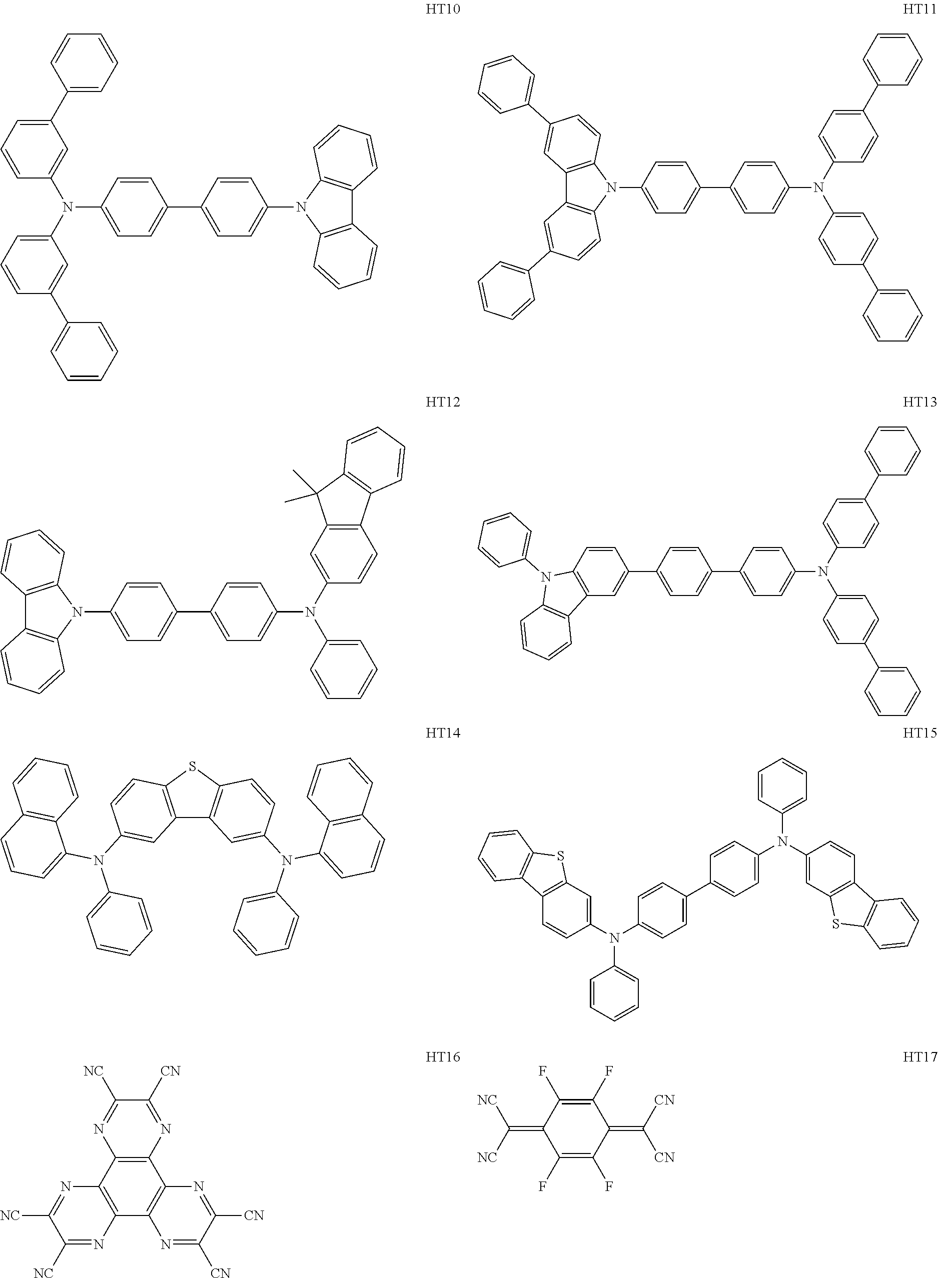

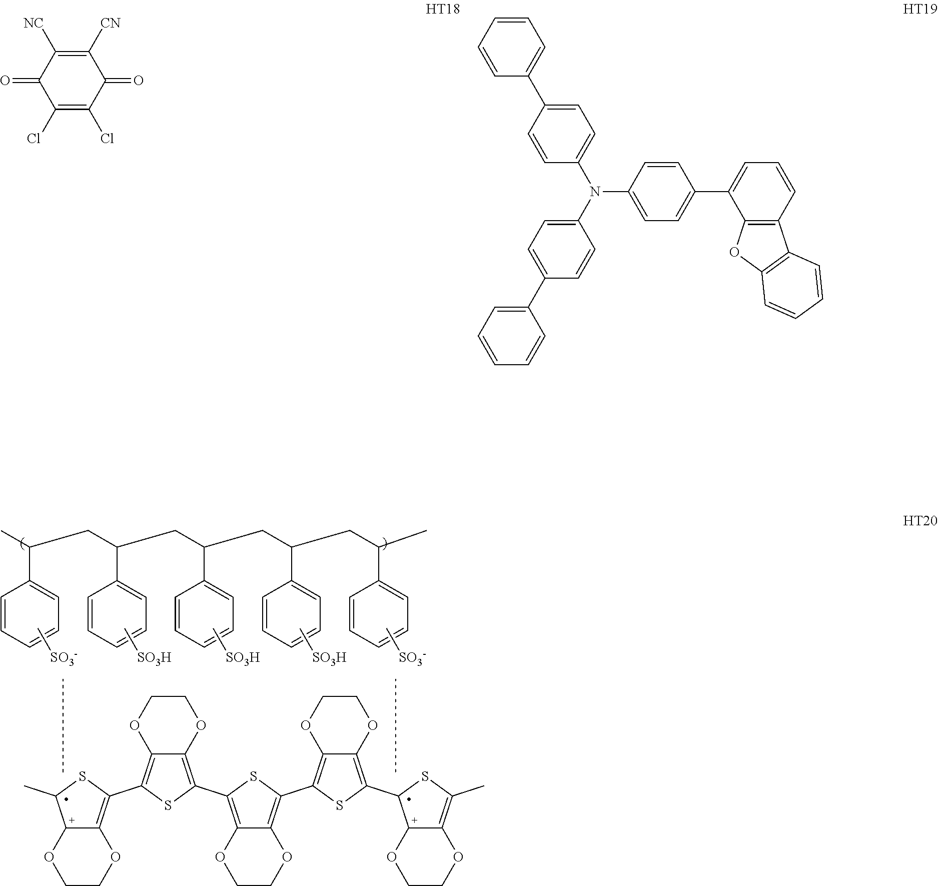

As the light-emitting material that is mainly associated with a light-emitting function, another light-emitting material can be added in addition to the organometallic complex according to an embodiment of the present invention. Examples of the other light-emitting material include fused ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes such as tris(8-quinolinolato)aluminum, iridium complexes such as tris(2-phenylpyridinato)iridium, platinum complexes, rhenium complexes, copper complexes, europium complexes, ruthenium complexes, and polymer derivatives such as poly(phenylene vinylene) derivatives, poly(fluorene) derivatives, and poly(phenylene) derivatives. Specific examples of the compound used as the light-emitting material are shown below, but of course, the light-emitting material is not limited thereto.

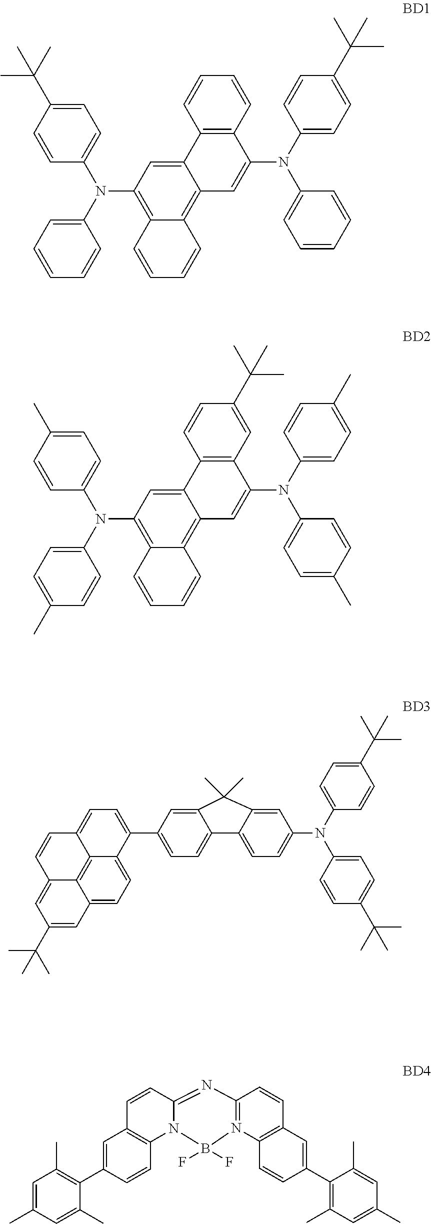

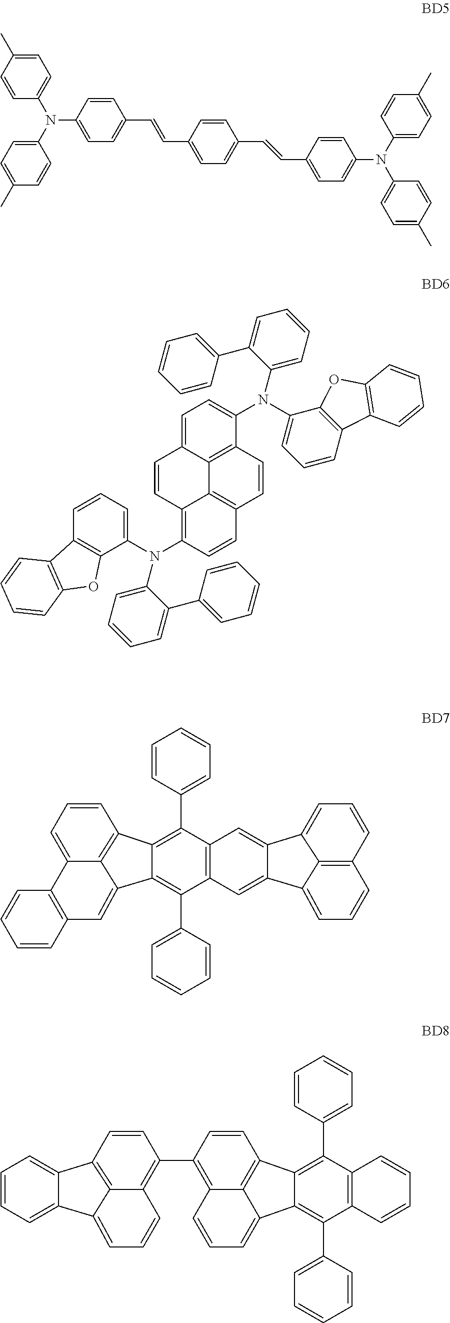

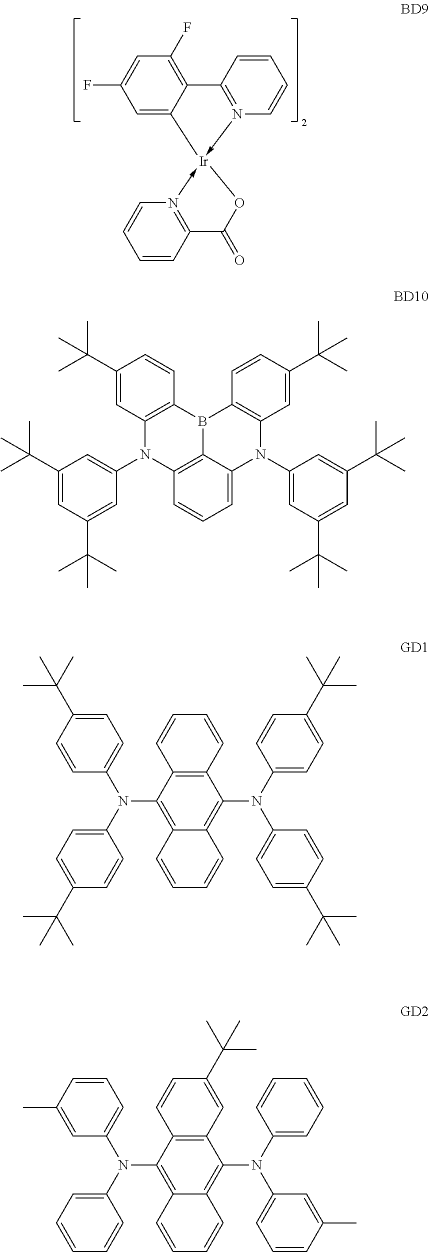

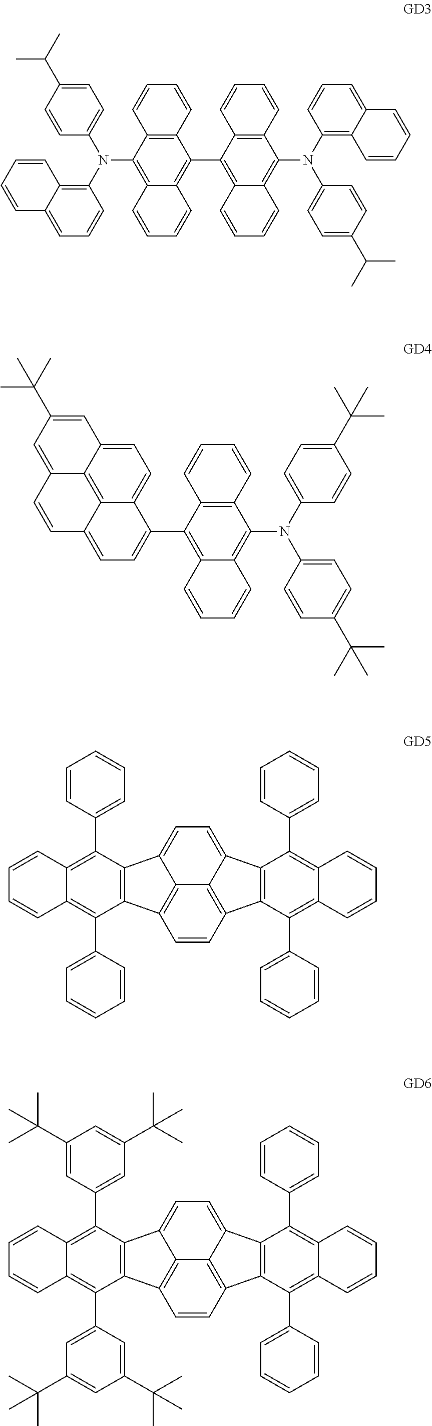

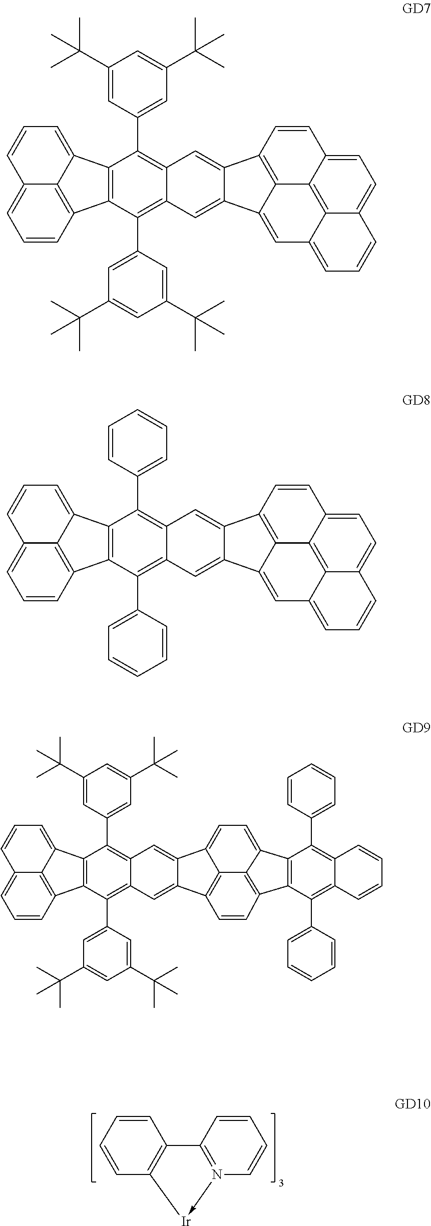

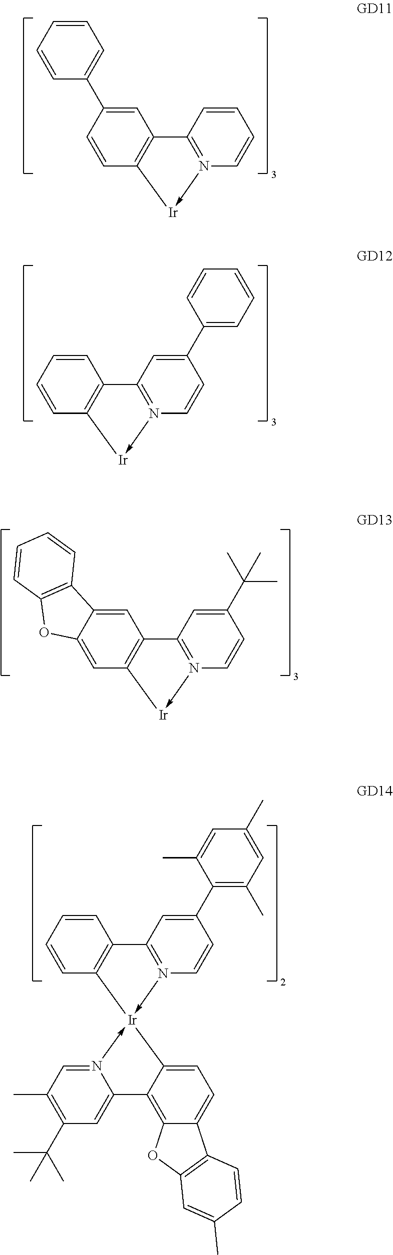

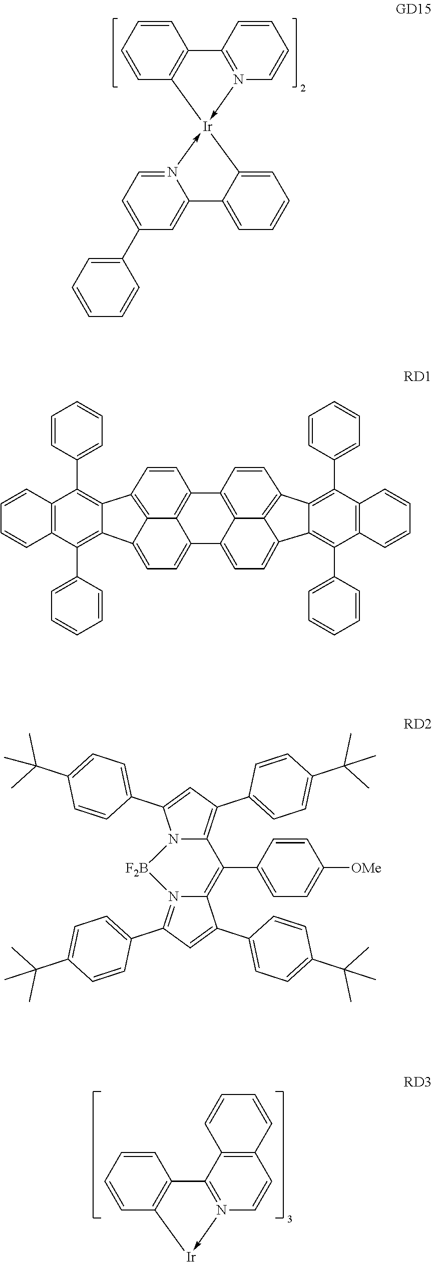

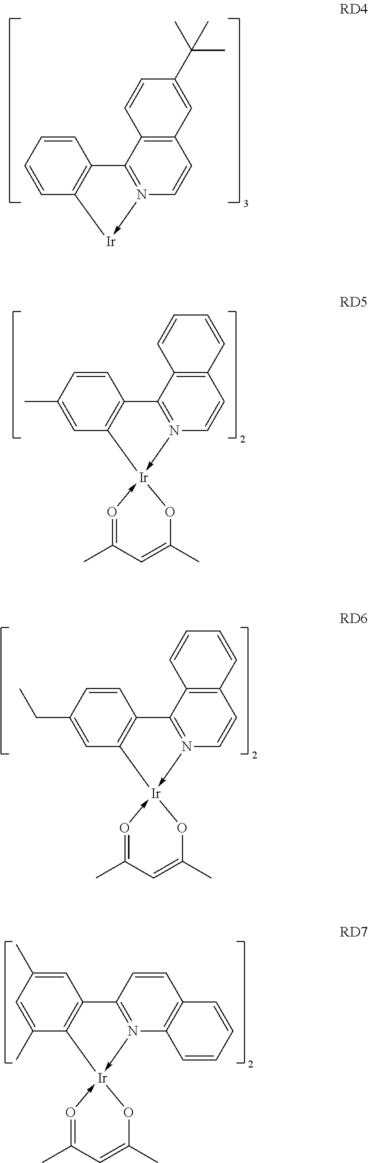

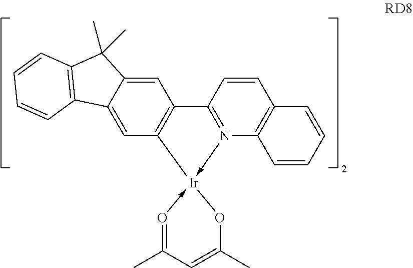

Examples of the light-emitting layer host or light-emitting assist material contained in the light-emitting layer include, in addition to aromatic hydrocarbon compounds and derivatives thereof, carbazole derivatives, dibenzofuran derivatives, dibenzothiophene derivatives, triazine derivatives, organoaluminum complexes such as tris(8-quinolinolato)aluminum, organoberyllium complexes, polymers such as polyphenylene derivatives, polyphenylene vinylene derivatives, polyfluorene derivatives, and polyvinyl carbazole derivatives, copolymers thereof, and mixtures thereof. Specific examples of the compound used as the light-emitting layer host or light-emitting assist material contained in the light-emitting layer are shown below, but of course, the light-emitting layer host or light-emission assist material is not limited thereto.

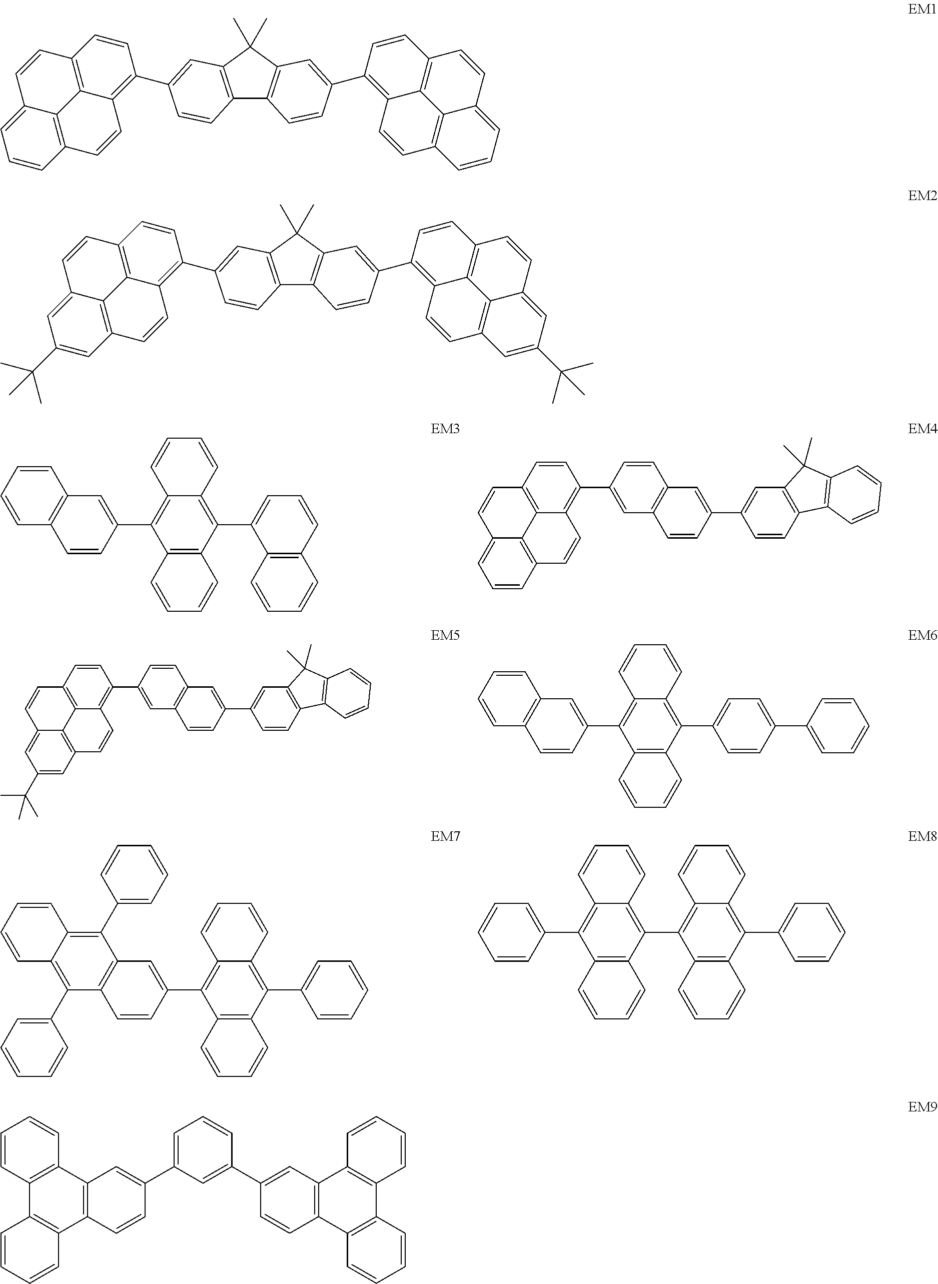

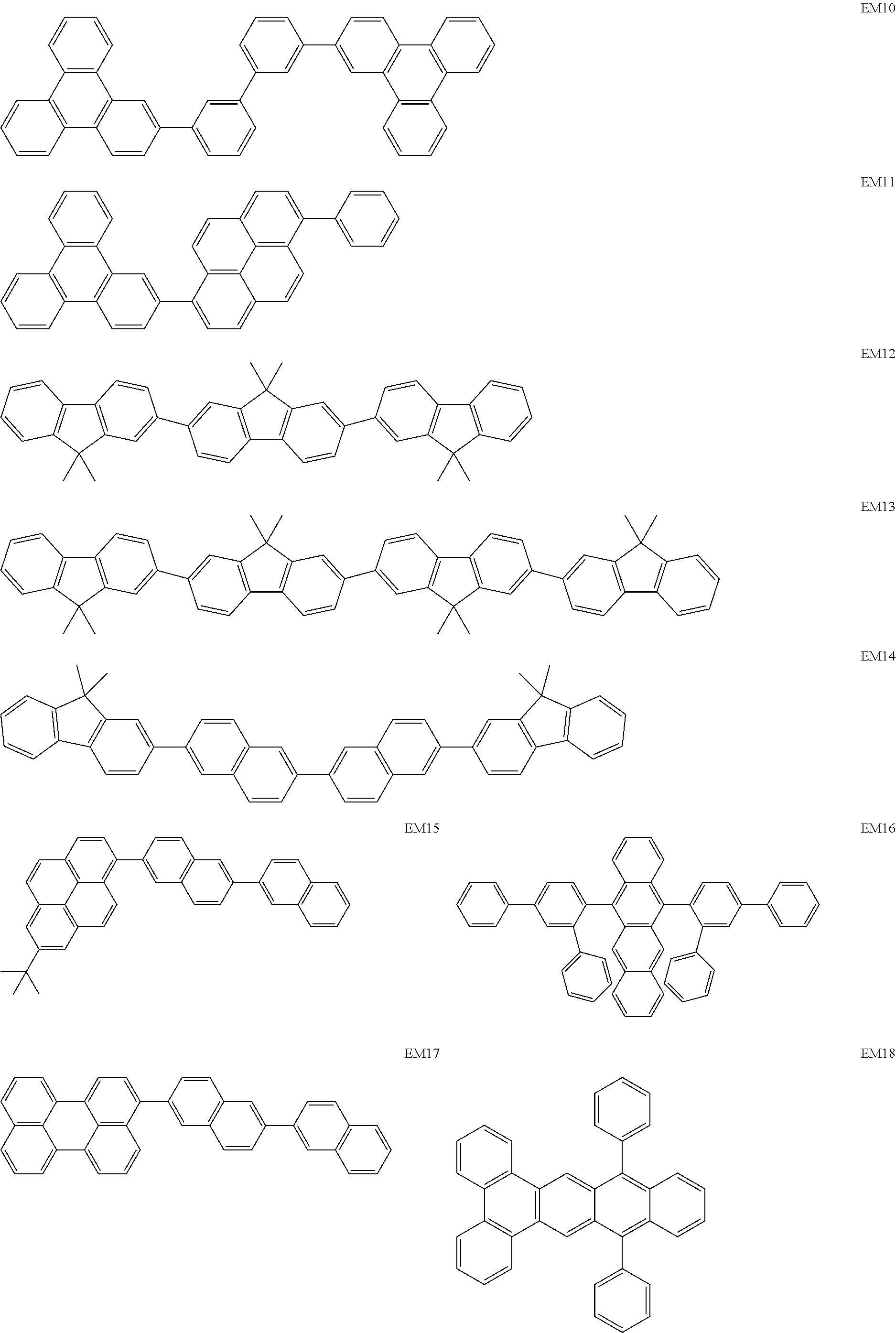

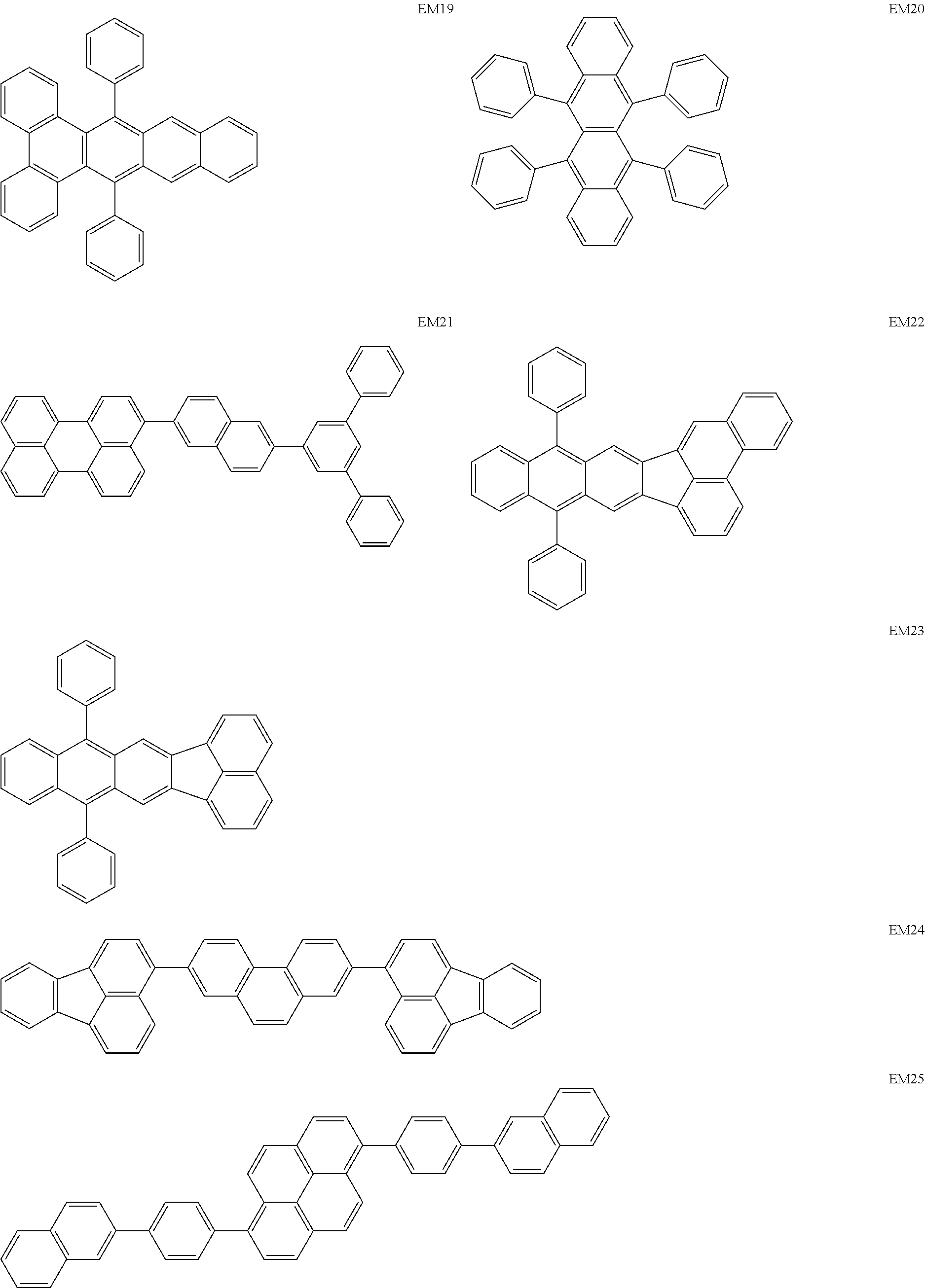

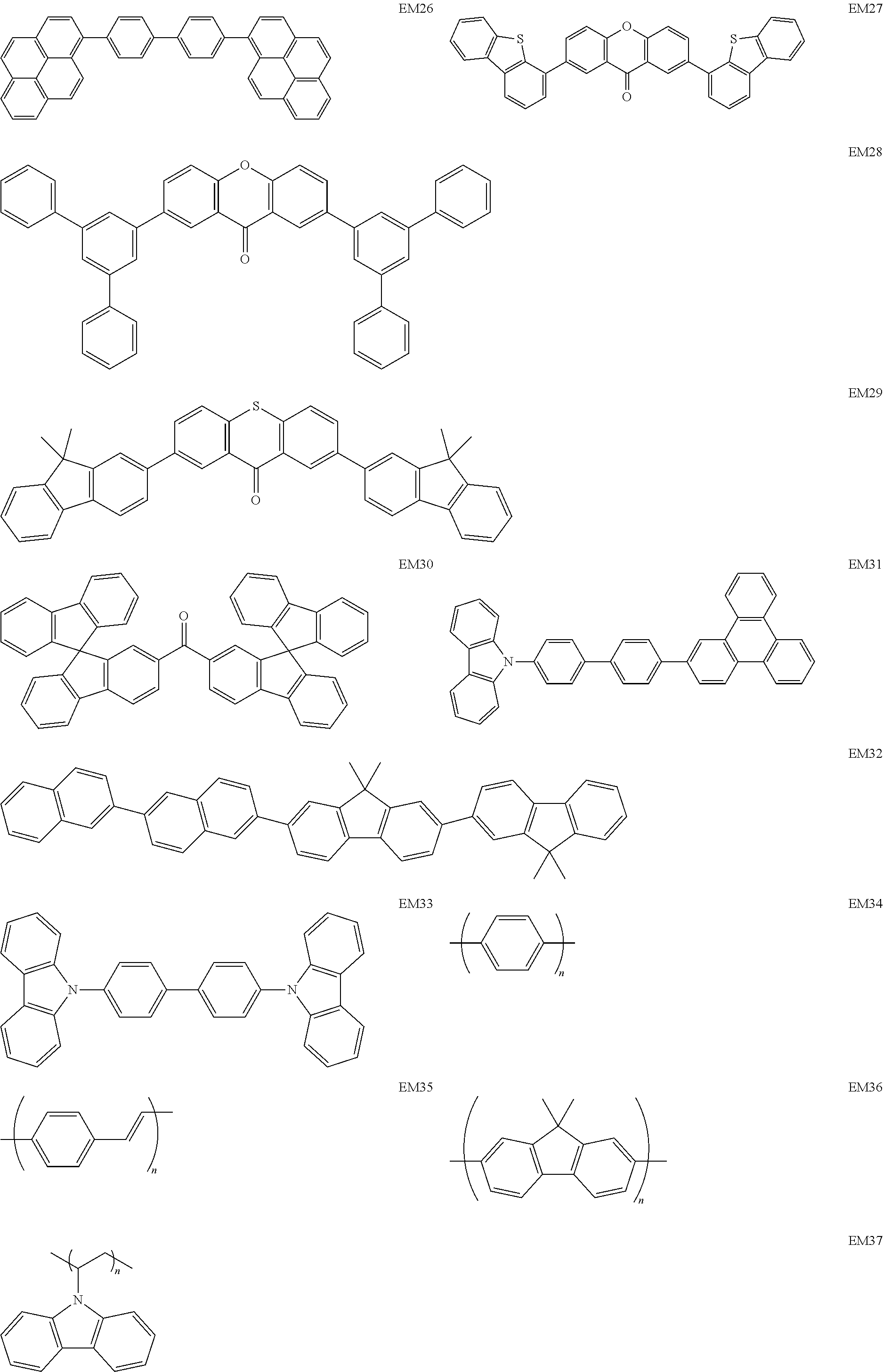

The electron transport material can be freely selected from materials capable of transporting electrons injected from the cathode to the light-emitting layer and is selected in consideration of, for example, the balance with the hole mobility of the hole transport material. Examples of the material having an electron transport property include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused ring compounds (such as fluorene derivatives, naphthalene derivatives, chrysene derivatives, and anthracene derivatives). The above electron transport materials are also suitable for use in a hole-blocking layer. Specific examples of the compound used as the electron transport material are shown below, but of course, the electron transport material is not limited thereto.

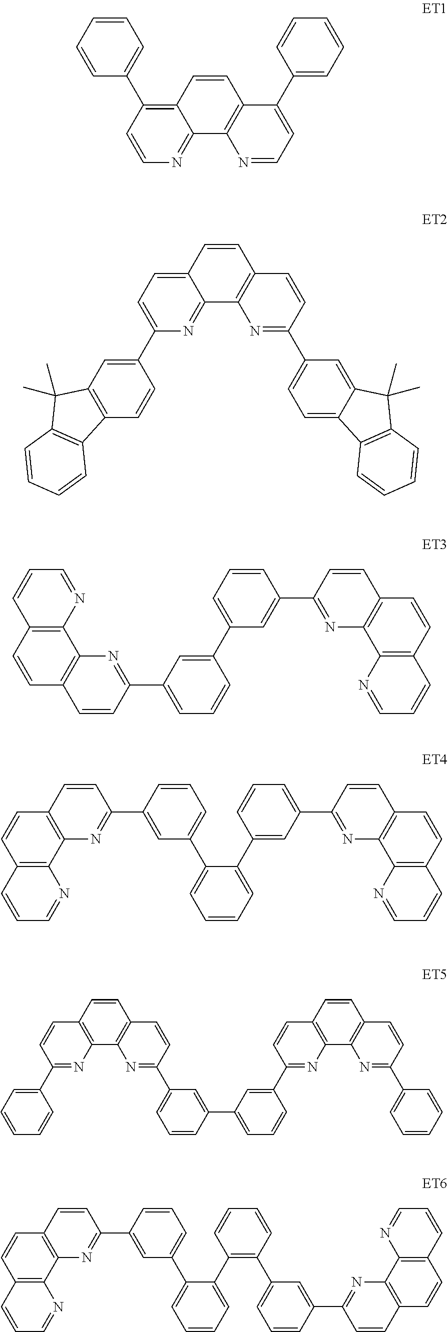

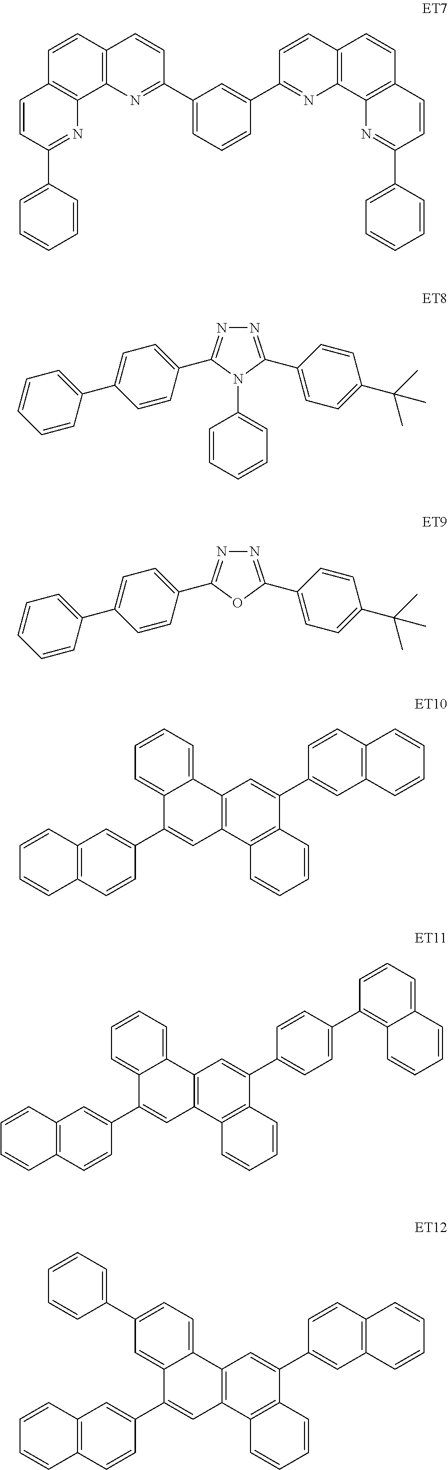

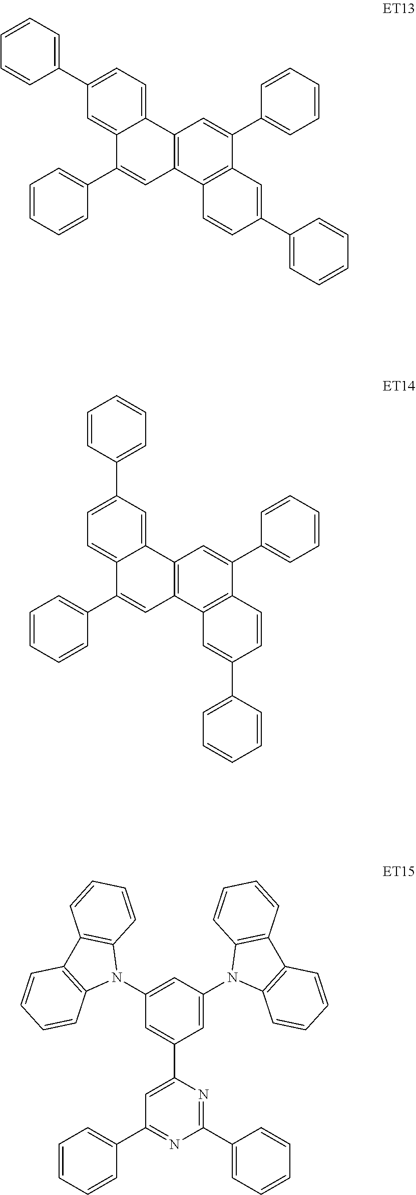

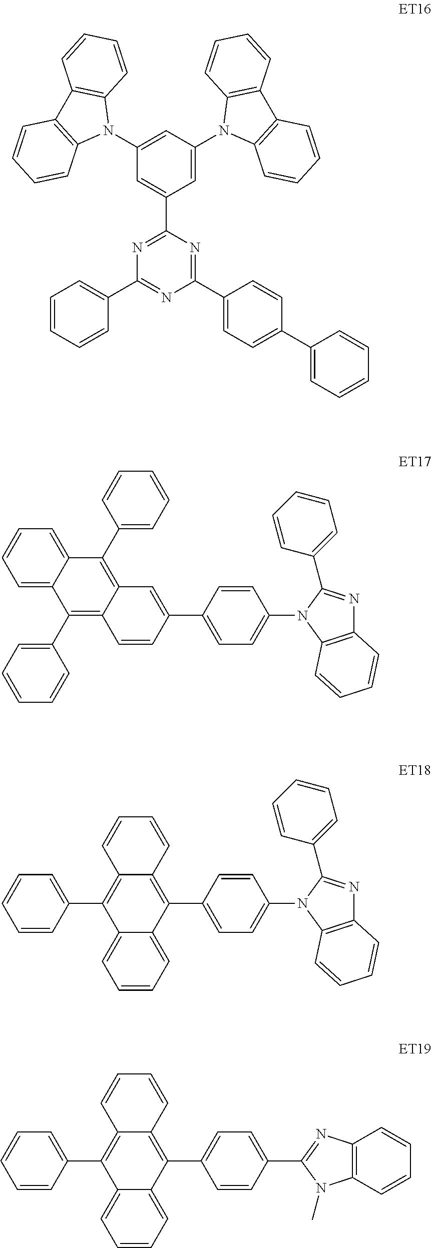 [SMILES: c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1 ; Cn1c(-c2ccc(-c3c4ccccc4c(-c4ccccc4)c4ccccc34)cc2)nc2ccccc21]

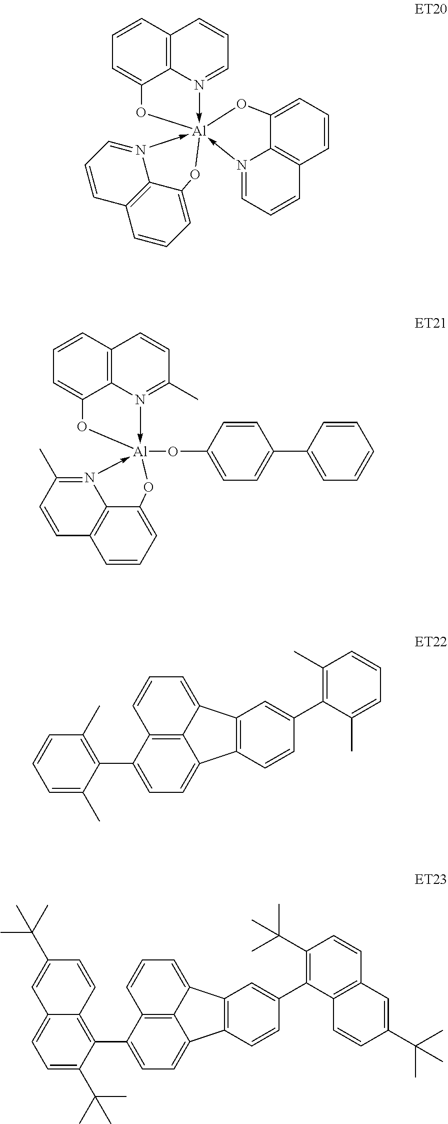

The electron injection material can be freely selected from materials capable of easily injecting electrons from the cathode and is selected in consideration of, for example, the balance with the hole injection property. As the organic compound, n-type dopants and reducing dopants are also included. Examples thereof include alkali metal-containing compounds such as lithium fluoride, lithium complexes such as lithium quinolinol, benzimidazolidene derivatives, imidazolidene derivatives, fulvalene derivatives, and acridine derivatives.

### Structure of Organic Light-Emitting Device

The organic light-emitting device is produced by forming an insulating layer, a first electrode, an organic compound layer, and a second electrode on a substrate. A protective layer, a color filter, a microlens, etc., may be disposed on the second electrode. When a color filter is provided, a planarization layer may be disposed between the color filter and the protective layer. The planarization layer can be formed of an acrylic resin or the like. This also applies to the case where a planarization layer is disposed between the color filter and the microlens.

### Substrate

Examples of the substrate include quartz substrates, glass substrates, silicon wafers, resin substrates, and metal substrates. Furthermore, switching elements, such as transistors, and wiring lines may be disposed on the substrate, and an insulating layer may be disposed thereon. The insulating layer may be formed of any material as long as a contact hole can be formed therein such that a wiring line can be connected to the first electrode and as long as insulation from an unconnected wiring line can be ensured. For example, a resin such as polyimide, silicon oxide, or silicon nitride can be used.

### Electrode

A pair of electrodes can be used as the electrodes. The pair of electrodes may be an anode and a cathode. In the case where an electric field is applied in a direction in which the organic light-emitting device emits light, an electrode with a higher electric potential is the anode, and the other electrode is the cathode. In other words, the electrode that supplies holes to the light-emitting layer is the anode, and the electrode that supplies electrons is the cathode.

The material constituting the anode can have a work function that is as large as possible. Examples of the material that can be used include elemental metals such as gold, platinum, silver, copper, nickel, palladium, cobalt, selenium, vanadium, and tungsten; mixtures containing these metals; alloys of combinations thereof; and metal oxides such as tin oxide, zinc oxide, indium oxide, indium tin oxide (ITO), and indium zinc oxide. Examples thereof further include conductive polymers such as polyaniline, polypyrrole, and polythiophene.

These electrode substances may be used alone or in combination of two or more thereof. The anode may be formed of a single layer or a plurality of layers.

When the anode is used as a reflective electrode, for example, chromium, aluminum, silver, titanium, tungsten, molybdenum, an alloy thereof, or a stacked layer thereof can be used. The above materials can be used to function as a reflective film that does not have a role of an electrode. When the anode is used as a transparent electrode, a transparent conductive oxide layer such as an indium tin oxide (ITO) or indium zinc oxide layer may be used; however, the anode is not limited thereto. The electrodes can be formed by photolithography.

In contrast, the material constituting the cathode can have a small work function. Examples of the material of the cathode include alkali metals such as lithium; alkaline earth metals such as calcium; elemental metals such as aluminum, titanium, manganese, silver, lead, and chromium; and mixtures containing these metals. Alloys of combinations of these elemental metals can also be used. For example, magnesium-silver, aluminum-lithium, aluminum-magnesium, silver-copper, and zinc-silver can be used. Metal oxides such as indium tin oxide (ITO) can also be used. These electrode substances may be used alone or in combination of two or more thereof. The cathode may have a single-layer structure or a multilayer structure. In particular, silver is preferably used. To reduce the aggregation of silver, a silver alloy is more preferably used. The alloying ratio is not limited as long as the aggregation of silver can be reduced. The ratio of silver to another metal may be, for example, 1:1 or 3:1.

The cathode is not particularly limited. The cathode may be a conductive oxide layer made of ITO or the like to provide a top-emission device. Alternatively, the cathode may be a reflective electrode made of aluminum (Al) or the like to provide a bottom-emission device. The method for forming the cathode is not particularly limited; however, for example, a DC or AC sputtering method is more preferably used because good film coverage is achieved and thus the resistance is easily reduced.

### Organic Compound Layer

The organic compound layer may be formed of a single layer or a plurality of layers. When the organic compound layer includes a plurality of layers, the layers may be referred to as a hole injection layer, a hole transport layer, an electron-blocking layer, a light-emitting layer, a hole-blocking layer, an electron transport layer, or an electron injection layer depending on their functions. The organic compound layer is mainly composed of an organic compound and may contain inorganic atoms and an inorganic compound. For example, the organic compound layer may contain copper, lithium, magnesium, aluminum, iridium, platinum, molybdenum, zinc, or the like. The organic compound layer may be disposed between the first electrode and the second electrode and may be disposed in contact with the first electrode and the second electrode.

The thickness of each of the layers in the organic light-emitting device is usually preferably 1 nm to 10 μm. In particular, the thickness of the light-emitting layer of the organic compound layer is preferably 10 nm to 100 nm in order to obtain effective emission characteristics.

The organic compound layers (such as a hole injection layer, a hole transport layer, an electron-blocking layer, a light-emitting layer, a hole-blocking layer, an electron transport layer, and an electron injection layer) constituting the organic light-emitting device according to one embodiment of the present invention are formed by the methods described below.

The organic compound layers constituting the organic light-emitting device according to one embodiment of the present invention can be formed by a dry process, such as a vacuum evaporation method, an ionized deposition method, sputtering, or plasma. Instead of the dry process, it is also possible to employ a wet process involving dissolving a material in an appropriate solvent, and then forming a layer by a publicly known coating method (for example, a Langmuir-Blodgett (LB) method, a spin coating method, a casting method, a microgravure coating method, a gravure coating method, a bar coating method, a roll coating method, a wire bar coating method, a dip coating method, a spray coating method, a screen printing method, a flexographic printing method, an offset printing method, an ink jet printing method, a capillary coating method, or a nozzle coating method). Of these, a vacuum evaporation method, an ionized deposition method, an ink jet printing method, a nozzle coating method, and the like are suitable for producing an organic light-emitting device having a large area.

When the layers are formed by a vacuum evaporation method, a coating method using a solution, or the like, the layers are unlikely to undergo, for example, crystallization and have good stability over time. When films are formed by a coating method, the materials can be combined with appropriate binder resins to form the films.

Examples of the binder resins include, but are not limited to, polyvinylcarbazole resins, polycarbonate resins, polyester resins, acrylonitrile-butadiene-styrene (ABS) resins, acrylic resins, polyimide resins, phenolic resins, epoxy resins, silicone resins, and urea resins.

These binder resins may be used alone as a homopolymer or a copolymer or in combination as a mixture of two or more thereof. Furthermore, publicly known additives such as a plasticizer, an oxidation inhibitor, and an ultraviolet absorbent may be optionally used in combination.

### Protective Layer

A protective layer may be disposed on the second electrode. For example, a glass member including a moisture absorbent is bonded to the second electrode to reduce the permeation of water or the like into the organic compound layer. Thus, the occurrence of display defects can be reduced. In another embodiment, a passivation film composed of silicon nitride or the like may be disposed on the second electrode to reduce the permeation of water or the like into the organic compound layer. For example, after the formation of the second electrode, the resulting substrate may be transferred to another chamber without breaking the vacuum, and a protective layer may be formed thereon by forming a silicon nitride film having a thickness of 2 μm by a CVD method. After the film deposition by the CVD method, a protective layer may be formed by an atomic layer deposition method (ALD method). The material of the film formed by the ALD method is not limited and may be, for example, silicon nitride, silicon oxide, or aluminum oxide. Silicon nitride may be further deposited by the CVD method on the film formed by the ALD method. The film formed by the ALD method may have a smaller thickness than the film formed by the CVD method. Specifically, the film thickness may be 50% or less, even 10% or less.

### Color Filter

A color filter may be disposed on the protective layer. For example, a color filter provided in consideration of the size of the organic light-emitting devices is disposed on another substrate, and this substrate may be bonded to the substrate having the organic light-emitting devices thereon. Alternatively, a color filter may be formed on the aforementioned protective layer by photolithographic patterning. The color filter may be formed of a polymer.

### Planarization Layer

A planarization layer may be disposed between the color filter and the protective layer. The planarization layer is formed in order to reduce unevenness of the underlying layer. In some cases, the planarization layer is referred to as a material resin layer without limiting the purpose thereof. The planarization layer may be formed of an organic compound. The organic compound may be a low-molecular-weight organic compound or a high-molecular-weight organic compound, but is preferably a high-molecular-weight organic compound.

The planarization layer may be disposed on and under the color filter, and both the planarization layers may be formed of the same material or different materials. Specific examples of the material include polyvinylcarbazole resins, polycarbonate resins, polyester resins, ABS resins, acrylic resins, polyimide resins, phenolic resins, epoxy resins, silicone resins, and urea resins.

### Microlens

An organic light-emitting device or an organic light-emitting apparatus may include an optical member such as a microlens on the light-emitting side. The microlens can be composed of an acrylic resin, an epoxy resin, or the like. The microlens may be used for the purposes of increasing the amount of light extracted from the organic light-emitting device or the organic light-emitting apparatus and controlling the direction of the extracted light. The microlens may have a hemispherical shape. When the microlens has a hemispherical shape, among tangents in contact with the hemisphere, there is a tangent parallel to the insulating layer, and the contact point between the tangent and the hemisphere is the apex of the microlens. The apex of the microlens can be determined in the same manner in any sectional view. That is, among the tangents in contact with the semicircle of the microlens in the sectional view, there is a tangent parallel to the insulating layer, and the contact point between the tangent and the semicircle is the apex of the microlens.

The midpoint of the microlens can also be defined. In a section of the microlens, an imaginary line segment extending from a point where the arc shape ends to another point where the arch shape ends is drawn, and the midpoint of the line segment can be referred to as the midpoint of the microlens. The section used to determine the apex and the midpoint may be a section perpendicular to the insulating layer.

### Opposite Substrate

An opposite substrate may be disposed on the planarization layer. The opposite substrate is disposed at a position that opposes the aforementioned substrate and thus is referred to as an opposite substrate. The material constituting the opposite substrate may be the same as that of the aforementioned substrate. The opposite substrate may be a second substrate if the aforementioned substrate is a first substrate.

### Pixel Circuit

An organic light-emitting apparatus having an organic light-emitting device may include a pixel circuit connected to the organic light-emitting device. The pixel circuit may be an active matrix-type circuit that independently controls light emission of a first light-emitting device and a second light-emitting device. The active matrix-type circuit may be a voltage programming or current programming circuit. A driving circuit has a pixel circuit for each pixel. The pixel circuit may have a light-emitting device, a transistor that controls the emission luminance of the light-emitting device, a transistor that controls the timing of light emission, a capacitor that holds the gate voltage of the transistor that controls the emission luminance, and a transistor for establishing the connection to GND without the light-emitting device.

The light-emitting apparatus has a display region and a peripheral region disposed around the display region. The display region includes a pixel circuit, and the peripheral region includes a display control circuit. The mobility of transistors constituting the pixel circuit may be smaller than the mobility of transistors constituting the display control circuit. The slope of the current-voltage characteristics of the transistors constituting the pixel circuit may be smaller than the slope of the current-voltage characteristics of the transistors constituting the display control circuit. The slope of the current-voltage characteristics can be measured by the so-called Vg-Ig characteristics. The transistors constituting the pixel circuit are transistors connected to light-emitting devices including the first light-emitting device.

### Pixel

The organic light-emitting apparatus having an organic light-emitting device may include a plurality of pixels. The pixels each include subpixels that emit light of a color different from the other colors. The subpixels may individually emit, for example, light of colors of RGB.

The pixels each emit light from an area that is also called a pixel aperture. This area is the same as a first area. The pixel aperture may have a size of 15 μm or less and 5 μm or more. More specifically, the pixel aperture may be, for example, 11 μm, 9.5 μm, 7.4 μm, or 6.4 μm. The distance between the subpixels may be 10 μm or less and may be specifically 8 μm, 7.4 μm, or 6.4 μm.

The pixels can have a publicly known arrangement form in plan view. For example, the arrangement form may be the stripe arrangement, the delta arrangement, the PenTile arrangement, or the Bayer arrangement. The subpixels may have any publicly known shape in plan view. For example, the shape may be a quadrangle such as a rectangle or a rhombus, or a hexagon. Of course, figures that are not exactly rectangles but are close to rectangles are also regarded as rectangles. The shape of the subpixels and the pixel arrangement can be used in combination.

### Application of Organic Light-Emitting Device

The organic light-emitting device according to the present embodiment can be used as a constituent member of a display apparatus or an illumination apparatus. In addition, the organic light-emitting device is used in, for example, an exposure light source of an electrophotographic image forming apparatus, a backlight of a liquid crystal display apparatus, and a light-emitting apparatus including a color filter on a white light source.

The display apparatus may be an image information processing apparatus that includes an image input unit to which image information is input from an area CCD, a linear CCD, a memory card, or the like and an information processing unit configured to process the input information, and that displays an input image on a display unit. The display apparatus may include a plurality of pixels, and at least one of the plurality of pixels may include the organic light-emitting device of the present embodiment and a transistor connected to the organic light-emitting device.

The display unit included in an imaging apparatus or an ink jet printer may have a touch panel function. The touch panel function may be operated by using infrared radiation, an electrostatic capacitance, a resistive film, or electromagnetic induction, and the operation method is not particularly limited. The display apparatus may be used in a display unit of a multifunctional printer.

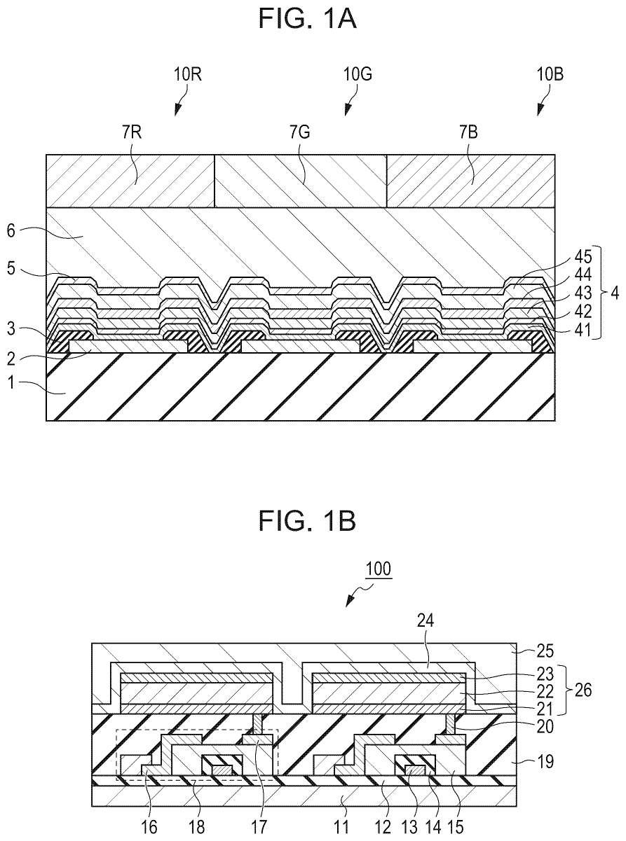

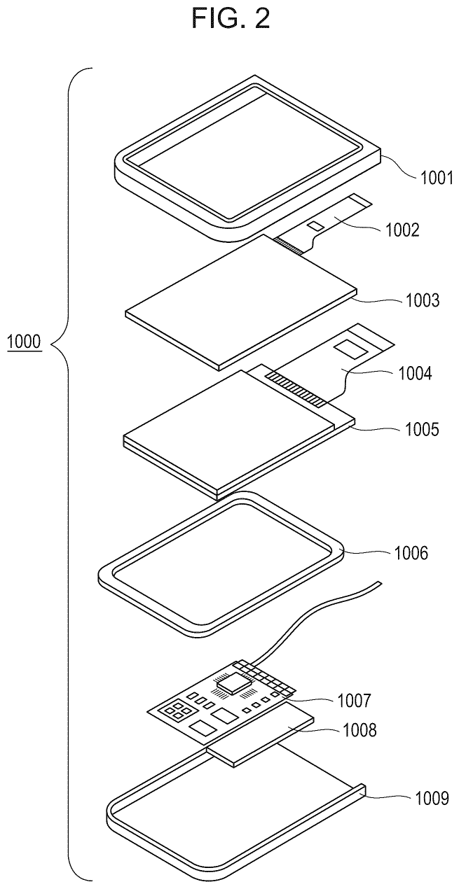

Next, a display apparatus according to the present embodiment will be described with reference to the drawings. FIGS. 1A and 1B are schematic sectional views illustrating an example of a display apparatus including organic light-emitting devices and transistors connected to the organic light-emitting devices. Each of the transistors is one example of an active element. The transistors may be thin-film transistors (TFT).

FIG. 1A is an example of a pixel which is a component of the display apparatus according to the present embodiment. A pixel has subpixels 10. The subpixels are separated into 10R, 10G, and 10B according to their light emission. The emission color may be distinguished on the basis of the wavelength of light emitted from the light-emitting layer, or the light emitted from the subpixels may be selectively transmitted or subjected to color conversion through a color filter or the like. Each of the subpixels 10 includes, on an interlayer insulating layer 1, a reflective electrode which is a first electrode 2, an insulating layer 3 covering ends of the first electrode 2, an organic compound layer 4 covering the first electrode 2 and the insulating layer 3, a transparent electrode which is a second electrode 5, a protective layer 6, and a color filter 7.

The interlayer insulating layer 1 may have transistors and capacitor elements arranged in a layer disposed thereunder or an interior thereof. Each transistor and the first electrode 2 may be electrically connected to each other through a contact hole or the like not illustrated in the drawing.

The insulating layer 3 is also called a bank or a pixel isolation film. The insulating layer 3 covers ends of the first electrode 2 and is disposed so as to surround the first electrode 2. The portion where the insulating layer 3 is not disposed is in contact with the organic compound layer 4 and serves as a light-emitting region.

The organic compound layer 4 includes a hole injection layer 41, a hole transport layer 42, a first light-emitting layer 43, a second light-emitting layer 44, and an electron transport layer 45.

The second electrode 5 may be a transparent electrode, a reflective electrode, or a semi-transparent electrode.

The protective layer 6 reduces the permeation of moisture into the organic compound layer 4. Although the protective layer 6 is illustrated as a single layer in the drawing, the protective layer 6 may be formed of a plurality of layers. Each layer may be an inorganic compound layer or an organic compound layer.

The color filter 7 is separated into 7R, 7G, and 7B according to the colors thereof. The color filter 7 may be formed on a planarizing film not illustrated in the drawing. Furthermore, a resin protective layer not illustrated in the drawing may be disposed on the color filter 7. The color filter 7 may be formed on the protective layer 6. Alternatively, the color filter 7 may be formed on an opposite substrate such as a glass substrate and may then be bonded.

A display apparatus 100 illustrated in FIG. 1B includes organic light-emitting devices 26 and TFTs 18 serving as one example of transistors. A substrate 11 composed of glass, silicon, or the like and an insulating layer 12 on top of the substrate 11 are provided. On the insulating layer 12, active elements such as TFTs 18 are disposed, and a gate electrode 13, a gate insulating film 14, and a semiconductor layer 15 of each of the active elements are disposed. Each of the TFTs 18 further includes a drain electrode 16 and a source electrode 17. An insulating film 19 is disposed on top of the TFTs 18. An anode 21 of each of the organic light-emitting devices 26 is connected to the source electrode 17 through a contact hole 20 formed in the insulating film 19.

The form of the electrical connection between the electrodes (anode 21 and cathode 23) included in each organic light-emitting device 26 and the electrodes (source electrode 17 and drain electrode 16) included in the corresponding one of the TFTs 18 is not limited to the form illustrated in FIG. 1B. In other words, any form may be employed as long as one of the anode 21 and the cathode 23 is electrically connected to one of the source electrode 17 and the drain electrode 16 of the TFT 18. The “TFT” refers to a thin-film transistor.

In the display apparatus 100 in FIG. 1B, an organic compound layer 22 is illustrated as if the organic compound layer 22 is formed of a single layer. Alternatively, the organic compound layer 22 may be formed of a plurality of layers. A first protective layer 24 and a second protective layer 25 for reducing degradation of the organic light-emitting devices 26 are disposed over cathodes 23.

Although transistors are used as the switching elements in the display apparatus 100 illustrated in FIG. 1B, different switching elements may be used instead of the transistors.

The transistors used in the display apparatus 100 illustrated in FIG. 1B are not limited to transistors that use a single-crystal silicon wafer but may be thin-film transistors that have an active layer on an insulating surface of a substrate. Examples of the active layer include layers of single-crystal silicon, non-single-crystal silicon such as amorphous silicon and microcrystalline silicon, and non-single-crystal oxide semiconductors such as indium zinc oxide and indium gallium zinc oxide. Thin-film transistors are also referred to as TFT elements.

The transistors included in the display apparatus 100 illustrated in FIG. 1B may be formed inside a substrate such as a Si substrate. The expression “formed inside a substrate” as used herein means that transistors are produced by processing a substrate, such as a Si substrate, itself. In other words, having transistors inside a substrate can also be considered that a substrate and transistors are integrally formed.

In the organic light-emitting device according to the present embodiment, the emission luminance is controlled by the TFTs, which are one example of switching elements, and thus an image can be displayed at respective emission luminance levels by arranging a plurality of organic light-emitting devices in a plane. The switching elements according to the present embodiment are not limited to TFTs and may be transistors formed of low-temperature polysilicon or active-matrix drivers formed on a substrate such as a Si substrate. The expression “on a substrate” can also be referred to as “inside the substrate”. Whether transistors are formed inside a substrate or TFTs are used is selected on the basis of the size of the display unit. For example, when the size is about 0.5 inches, organic light-emitting devices are preferably disposed on a Si substrate.

FIG. 2 is a schematic view illustrating an example of a display apparatus according to the present embodiment. A display apparatus 1000 may include an upper cover 1001 and a lower cover 1009, and a touch panel 1003, a display panel 1005, a frame 1006, a circuit board 1007, and a battery 1008 that are disposed between the upper cover 1001 and the lower cover 1009. The touch panel 1003 and the display panel 1005 are connected to flexible printed circuits FPC 1002 and 1004, respectively. Transistors are printed on the circuit board 1007. The battery 1008 is not necessarily installed unless the display apparatus is a portable apparatus or may be installed in a different position even if the display apparatus is a portable apparatus.

The display apparatus according to the present embodiment may include a color filter having red, green, and blue portions. The red, green, and blue portions of the color filter may be arranged in the delta arrangement, a stripe arrangement, or a mosaic arrangement.

The display apparatus according to the present embodiment may be used in a display unit of a portable terminal. In such a case, the display apparatus may have both a display function and an operation function. Examples of the portable terminal include mobile phones such as smart phones, tablets, and head mount displays.

The display apparatus according to the present embodiment may be used in a display unit of an imaging apparatus including an optical unit including a plurality of lenses and an imaging device that receives light that has passed through the optical unit. The imaging apparatus may include a display unit that displays information acquired by the imaging device. The display unit may be a display unit exposed to the outside of the imaging apparatus or a display unit disposed in a viewfinder. The imaging apparatus may be a digital camera or a digital camcorder.

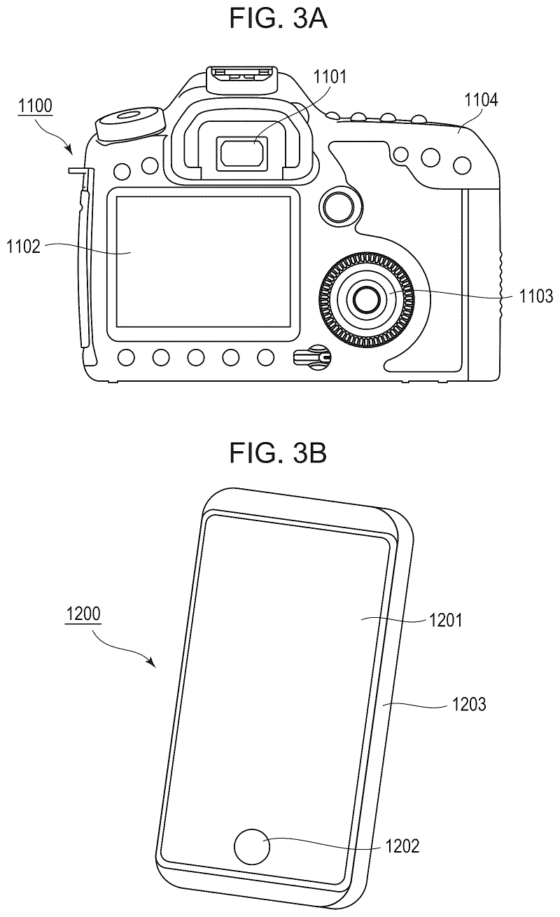

FIG. 3A is a schematic view illustrating an example of an imaging apparatus according to the present embodiment. An imaging apparatus 1100 may include a viewfinder 1101, a rear surface display 1102, an operation unit 1103, and a housing 1104. The viewfinder 1101 may include a display apparatus according to the present embodiment. In such a case, the display apparatus may display not only an image to be captured but also, for example, environmental information and imaging instructions. The environmental information may include, for example, the intensity of external light, the direction of external light, the moving speed of the subject, and the possibility that the subject may hide behind an obstacle.

Since the suitable timing for capturing an image is a very short period of time, it is desirable to display information as quickly as possible. Accordingly, a display apparatus that uses the organic light-emitting device of the present embodiment is preferably used. This is because the organic light-emitting device has a high response speed. The display apparatus that uses the organic light-emitting device can be used more suitably than liquid crystal display apparatuses for such apparatuses required to have a high display speed.

The imaging apparatus 1100 includes an optical unit not illustrated in the drawing. The optical unit includes a plurality of lenses and is configured to form an image on an imaging device contained in the housing 1104. By adjusting the relative positions of the plurality of lenses, the focal point can be adjusted. This operation can also be performed automatically. The imaging apparatus may also be referred to as a photoelectric conversion apparatus. The photoelectric conversion apparatus can employ, instead of a method of successively capturing images, image capturing methods such as a method of detecting a difference from the previous image and a method of extracting images from continuously recorded images.

FIG. 3B is a schematic view of an example of an electronic apparatus according to the present embodiment. An electronic apparatus 1200 includes a display unit 1201, an operation unit 1202, and a housing 1203. The housing 1203 may include therein circuits, a printed circuit board having the circuits, a battery, and a communication unit. The operation unit 1202 may be a button or a touch panel-type responsive unit. The operation unit 1202 may be a biometric authentication unit configured to, for example, recognize the fingerprints and release the lock. The electronic apparatus that includes a communication unit can also be referred to as a communication apparatus. The electronic apparatus 1200 may include a lens and an imaging device so as to further have a camera function. An image captured by the camera function is displayed on the display unit 1201. Examples of the electronic apparatus 1200 include smart phones and notebook computers.

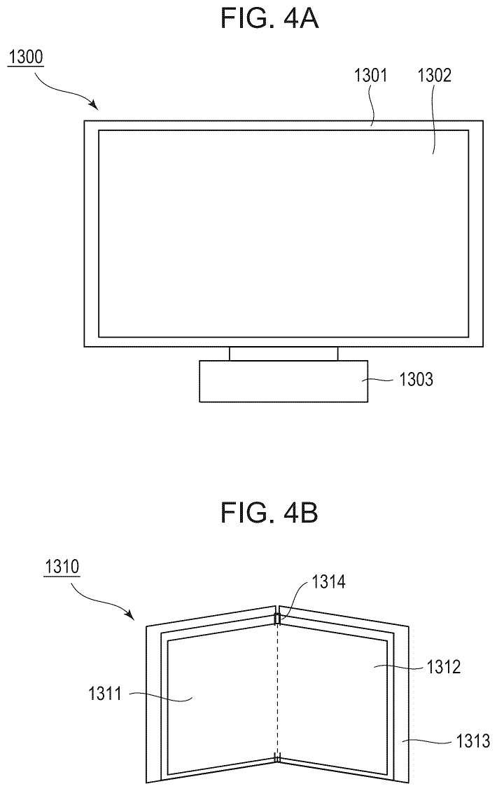

FIGS. 4A and 4B are schematic views each illustrating an example of a display apparatus according to the present embodiment. FIG. 4A illustrates a display apparatus such as a television monitor or a PC monitor. A display apparatus 1300 includes a frame 1301 and a display unit 1302. The light-emitting device according to the present embodiment may be used in the display unit 1302. The display apparatus 1300 further includes a base 1303 that supports the frame 1301 and the display unit 1302. The base 1303 is not limited to the form illustrated in FIG. 4A. The lower side of the frame 1301 may also function as the base. The frame 1301 and the display unit 1302 may be curved. The radius of curvature thereof may be 5,000 mm or more and 6,000 mm or less.

FIG. 4B is a schematic view illustrating another example of the display apparatus according to the present embodiment. A display apparatus 1310 illustrated in FIG. 4B is configured to be foldable and is a so-called foldable display apparatus. The display apparatus 1310 has a first display unit 1311, a second display unit 1312, a housing 1313, and a folding point 1314. Each of the first display unit 1311 and the second display unit 1312 may include the light-emitting device accordion to the present embodiment. The first display unit 1311 and the second display unit 1312 may be a single display apparatus without a joint. The first display unit 1311 and the second display unit 1312 can be separated at the folding point. The first display unit 1311 and the second display unit 1312 may respectively display different images. Alternatively, a single image may be displayed on a set of the first and second display units.

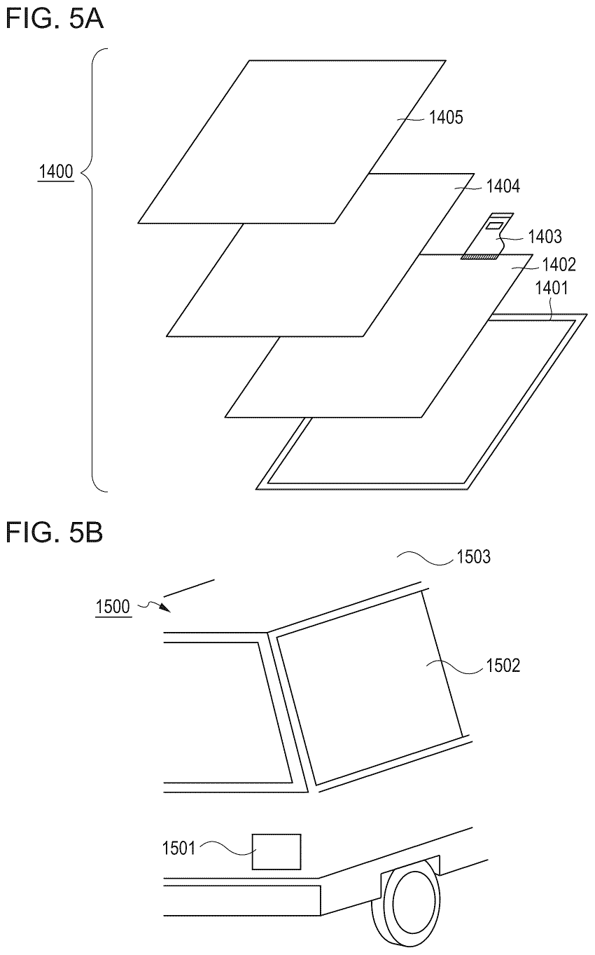

FIG. 5A is a schematic view illustrating an example of an illumination apparatus according to the present embodiment. An illumination apparatus 1400 may include a housing 1401, a light source 1402, a circuit board 1403, an optical filter 1404 and a light diffusion unit 1405 that transmit light emitted from the light source 1402. The light source 1402 may include the organic light-emitting device according to the present embodiment. The optical filter 1404 may be a filter that improves the color rendering properties of the light source. The light diffusion unit 1405 can effectively diffuse light emitted from the light source and allow the light to reach a wide range, for example, for lighting up. The optical filter 1404 and the light diffusion unit 1405 may be disposed on the light-emitting side of the illumination. A cover may be optionally disposed on the outermost portion.

The illumination apparatus is, for example, an apparatus that illuminates a room. The illumination apparatus may emit light of a color such as white, natural white, or any other color from blue to red. The illumination apparatus may include a light modulating circuit configured to modulate the light. The illumination apparatus may include the organic light-emitting device according to the present embodiment and a power supply circuit connected to the organic light-emitting device. The power supply circuit is a circuit configured to convert an AC voltage into a DC voltage. The white is a color having a color temperature of 4,200 K, and the natural white is a color having a color temperature of 5,000 K. The illumination apparatus may include a color filter.

The illumination apparatus according to the present embodiment may include a heat dissipation unit. The heat dissipation unit dissipates heat in the apparatus to the outside of the apparatus. The heat dissipation unit may be formed of, for example, a metal having a high specific heat or liquid silicone.

FIG. 5B is a schematic view of an automobile, which is an example of a moving object according to the present embodiment. The automobile has a tail lamp, which is an example of a lighting fixture. An automobile 1500 has a tail lamp 1501, and the tail lamp 1501 may light up when, for example, the brakes are applied.

The tail lamp 1501 may include the organic light-emitting device according to the present embodiment. The tail lamp 1501 may include a protective member that protects the organic light-emitting device. The protective member may be composed of any material that has high strength to a certain extent and is transparent, and is preferably composed of polycarbonate or the like. The polycarbonate may be mixed with a furandicarboxylic acid derivative, an acrylonitrile derivative, or the like.

The automobile 1500 may include a car body 1503 and a window 1502 attached to the car body 1503. The window 1502 may be a transparent display unless it is a window for checking the front and rear of the automobile. The transparent display may include the organic light-emitting device according to the present embodiment. In such a case, the components, such as the electrodes, of the organic light-emitting device are formed of transparent members.

The moving object according to the present embodiment may be, for example, a ship, an aircraft, or a drone. The moving object may include a body and a lighting fixture attached to the body. The lighting fixture may emit light to indicate the position of the body. The lighting fixture includes the organic light-emitting device according to the present embodiment.

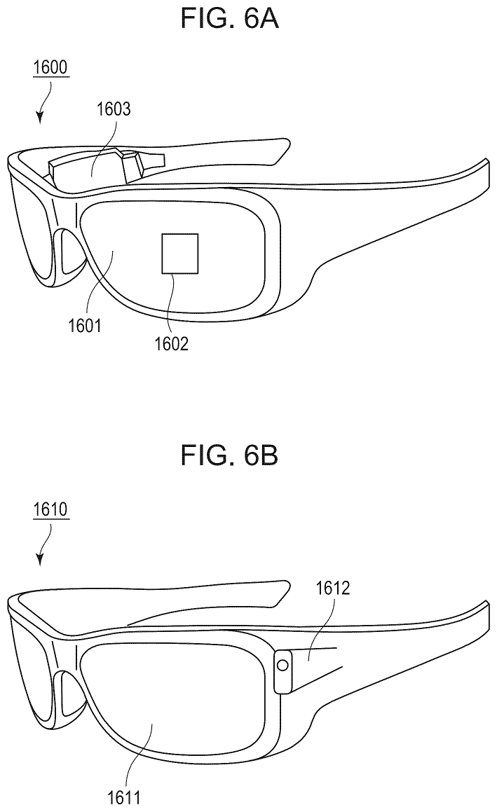

Examples of applications of the display apparatuses according to the embodiments described above will be described with reference to FIGS. 6A and 6B. The display apparatuses are applicable to systems that can be worn as wearable devices, such as smart glasses, head mount display (HMDs), and smart contact lenses. An imaging and display apparatus used in such an example of the application includes an imaging apparatus that can photoelectrically convert visible light and a display apparatus that can emit visible light.

FIG. 6A is a schematic view illustrating an example of a wearable device according to an embodiment of the present invention. Glasses 1600 (smart glasses) according to one example of applications will be described with reference to FIG. 6A. An imaging apparatus 1602 such as a complementary metal-oxide semiconductor (CMOS) sensor or a single-photon avalanche diode (SPAD) is disposed on a front side of a lens 1601 of the glasses 1600. The display apparatus according to any of the above-described embodiments is disposed on a back side of the lens 1601.

The glasses 1600 further include a control unit 1603. The control unit 1603 functions as a power supply that supplies electric power to the imaging apparatus 1602 and the display apparatus. The control unit 1603 also controls the operation of the imaging apparatus 1602 and the display apparatus. An optical system for focusing light on the imaging apparatus 1602 is formed in the lens 1601.

FIG. 6B is a schematic view illustrating another example of the wearable device according to an embodiment of the present invention. Glasses 1610 (smart glasses) according to one example of applications will be described with reference to FIG. 6B. The glasses 1610 have a control unit 1612. The control unit 1612 includes an imaging apparatus corresponding to the imaging apparatus 1602 in FIG. 6A and a display apparatus. An optical system for projecting light emitted from the display apparatus and the imaging apparatus in the control unit 1612 is formed in a lens 1611, and an image is projected onto the lens 1611. The control unit 1612 functions as a power supply that supplies electric power to the imaging apparatus and the display apparatus and also controls the operation of the imaging apparatus and the display apparatus.

The control unit 1612 may have a gaze detection unit that detects the gaze of the wearer. Infrared rays may be used to detect the gaze. An infrared light-emitting unit emits infrared light toward an eyeball of the user who is gazing at a displayed image. A captured image of the eyeball is obtained when an imaging unit including a light-receiving device detects reflection of the emitted infrared light from the eyeball. The degradation of the image quality is reduced by providing reducing means for reducing light from the infrared light-emitting unit to a display unit in plan view. The gaze of the user with respect to the displayed image is detected from the captured image of the eyeball captured with the infrared light. Any publicly known method is applicable to the gaze detection using the captured image of the eyeball. As one example, a gaze detection method based on the Purkinje image formed by reflection of irradiation light on the cornea can be employed. More specifically, a gaze detection process based on a pupil-corneal reflection method is performed. The gaze of the user is detected using the pupil-corneal reflection method by calculating a gaze vector that indicates the direction (rotation angle) of the eyeball on the basis of the image of the pupil and the Purkinje image included in the captured image of the eyeball.

The display apparatus according to an embodiment of the present invention may include an imaging apparatus including a light-receiving device, and may control a displayed image of the display apparatus on the basis of the gaze information of the user from the imaging apparatus. Specifically, the display apparatus determines a first field-of-view region at which the user gazes and a second field-of-view region other than the first field-of-view region on the basis of the gaze information. The first field-of-view region and the second field-of-view region may be determined by the control unit of the display apparatus or may be determined by receiving those determined by an external control unit. In the display region of the display apparatus, the display resolution of the first field-of-view region may be controlled to be higher than the display resolution of the second field-of-view region. In other words, the resolution of the second field-of-view region may be lower than that of the first field-of-view region.

The display region includes a first display region and a second display region different from the first display region. A region of higher priority is determined from the first display region and the second display region on the basis of the gaze information. The first display region and the second display region may be determined by the control unit of the display apparatus or may be determined by receiving those determined by an external control unit. The resolution of the region of higher priority may be controlled to be higher than the resolution of the region other than the region of higher priority. In other words, the resolution of a region of a relatively low priority may be low.

Artificial intelligence (AI) may be used to determine the first field-of-view region or the region of higher priority. The AI may be a model configured to estimate the angle of the gaze and the distance to a target object at the end of the gaze from the image of the eyeball by using, as teaching data, the image of the eyeball and the direction in which the eyeball in the image was actually gazing. The AI program may be stored in the display apparatus, the imaging apparatus, or an external apparatus. When the AI program is stored in an external apparatus, the AI program is transmitted through communication to the display apparatus.

In the case of controlling the display on the basis of visual recognition, smart glasses further including an imaging apparatus that captures an external image are suitable for use. The smart glasses can display the captured external information in real time.

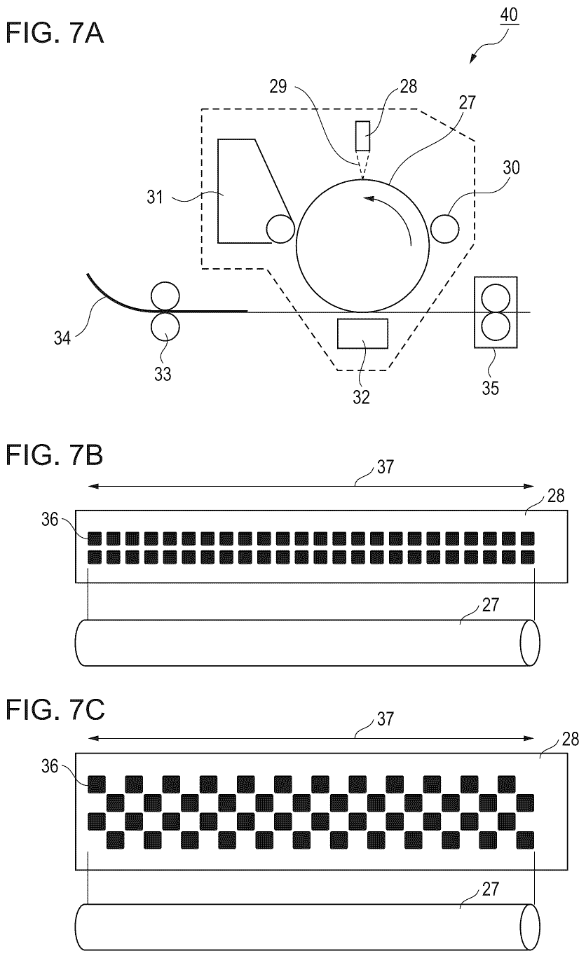

FIG. 7A is a schematic diagram illustrating an example of an image forming apparatus according to an embodiment of the present invention. An image forming apparatus 40 is an electrophotographic image forming apparatus and includes a photoreceptor 27, an exposure light source 28, a charging portion 30, a developing portion 31, a transfer unit 32, transport rollers 33, and a fixing unit 35. Light 29 is applied from the exposure light source 28, and an electrostatic latent image is formed on the surface of the photoreceptor 27. The exposure light source 28 includes the organic light-emitting device according to the present embodiment. The developing portion 31 contains a toner and the like. The charging portion 30 charges the photoreceptor 27. The transfer unit 32 transfers a developed image to a recording medium 34. The transport rollers 33 transport the recording medium 34. The recording medium 34 is, for example, paper. The fixing unit 35 fixes the image formed on the recording medium 34.

FIGS. 7B and 7C are views illustrating the exposure light source 28 and are schematic views illustrating a plurality of light-emitting portions 36 arranged on a long substrate. An arrow 37 indicates a direction parallel to the axis of the photoreceptor, that is, a row direction in which the organic light-emitting devices are arranged. The row direction is the same as the direction of the rotational axis of the photoreceptor 27. This direction can also be referred to as a long-axis direction of the photoreceptor 27. FIG. 7B illustrates a form in which the light-emitting portions 36 are arranged in the long-axis direction of the photoreceptor 27. FIG. 7C illustrates a form which is different from that in FIG. 7B and in which the light-emitting portions 36 are alternately arranged in the row direction in a first row and a second row. The first row and the second row are arranged at different positions in a column direction. In the first row, the plurality of light-emitting portions 36 are arranged at intervals. The second row has the light-emitting portions 36 at positions corresponding to the spaces between the light-emitting portions 36 of the first row. In other words, the plurality of light-emitting portions 36 are also arranged at intervals in the column direction. The arrangement in FIG. 7C can also be referred to as, for example, a lattice arrangement, a staggered arrangement, or a checkered pattern.

As described above, the use of an apparatus including the organic light-emitting device according to the present embodiment enables a stable display for a long time with good image quality.

Features that are Included

The disclosure of the present embodiment includes the following features.

### Feature 1

A metal complex represented by general formula (1) above.

### Feature 2

The metal complex according to feature 1, wherein M is Pt.

### Feature 3

The metal complex according to feature 1 or 2, wherein at least one of R₈ and R₉ is an alkyl group having 2 or more carbon atoms.

### Feature 4

The metal complex according to any one of features 1 to 3, wherein X—Y is an acetylacetonate derivative.

### Feature 5

The metal complex according to any one of features 1 to 4, being represented by general formula (2) above.

### Feature 6

An organic light-emitting device including an anode, a cathode, and an organic compound layer disposed between the anode and the cathode,
wherein at least one layer in the organic compound layer contains the metal complex according to any one of features 1 to 5.

### Feature 7

The organic light-emitting device according to feature 6, wherein the layer containing the metal complex is a light-emitting layer.

### Feature 8

The organic light-emitting device according to feature 7, wherein the metal complex is a light-emitting dopant.

### Feature 9

A display apparatus including a plurality of pixels, wherein at least one of the plurality of pixels includes the organic light-emitting device according to any one of features 6 to 8 and a transistor connected to the organic light-emitting device.

### Feature 10

A photoelectric conversion apparatus including an optical unit including a plurality of lenses, an imaging device that receives light that has passed through the optical unit, and a display unit that displays an image captured by the imaging device,
wherein the display unit includes the organic light-emitting device according to any one of features 6 to 8.

### Feature 11

An electronic apparatus including a display unit including the organic light-emitting device according to any one of features 6 to 8, a housing provided with the display unit, and a communication unit that is disposed in the housing and communicates with an external unit.

### Feature 12

An illumination apparatus including a light source including the organic light-emitting device according to any one of features 6 to 8, and a light diffusion unit or an optical filter that transmits light emitted from the light source.

### Feature 13

A moving object including a lighting fixture including the organic light-emitting device according to any one of features 6 to 8, and a body provided with the lighting fixture.

### Feature 14

An exposure light source for an electrophotographic image forming apparatus, the exposure light source including the organic light-emitting device according to any one of features 6 to 8.

### EXAMPLES

Examples will be described below. However, the present invention is not limited to these examples.

First, Comparative example compounds 01 to 03 and Example compounds 01 to 04 used in the examples are shown below.

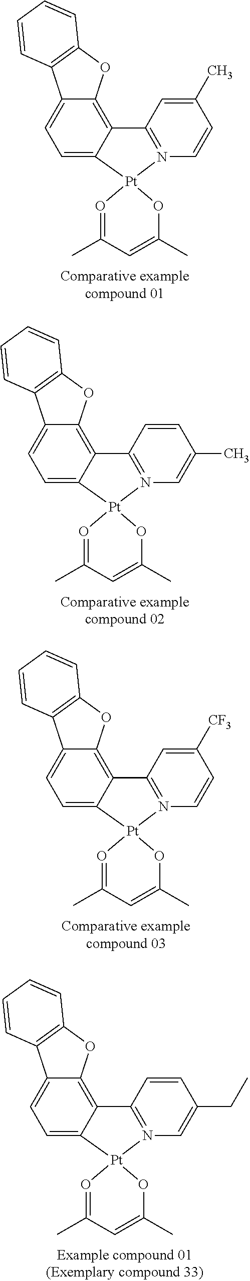

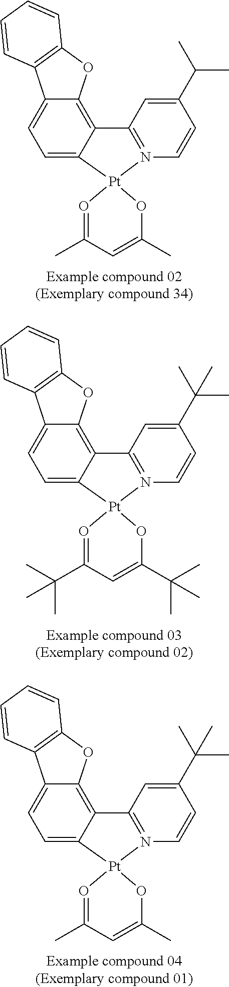

### Example 1

Example compounds 01 to 04 and Comparative example compounds 01 to 03 were synthesized in accordance with the synthesis methods of NPL 2. As a typical example, a synthesis scheme of Example compound 03 is shown below.

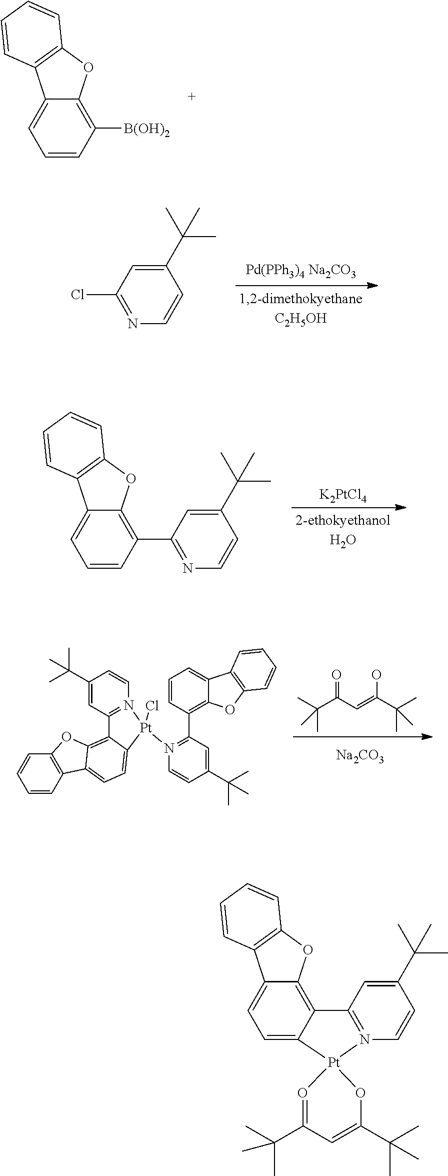

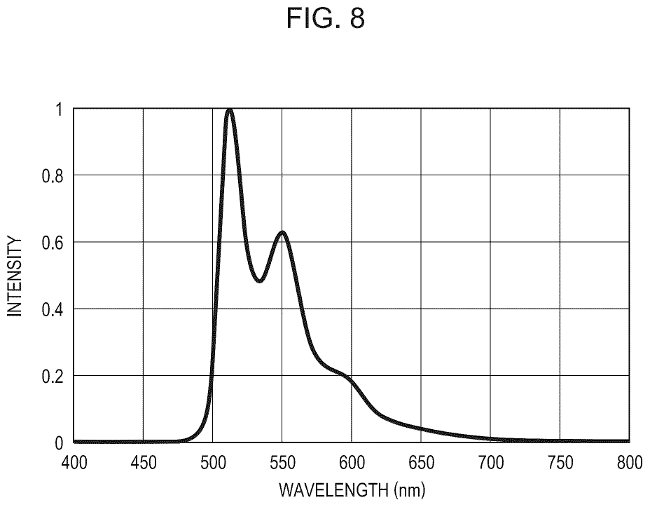

FIG. 8 shows an emission spectrum of Example compound 03 in a toluene solvent (10⁻⁵ M). The emission peak wavelength is 513 nm.

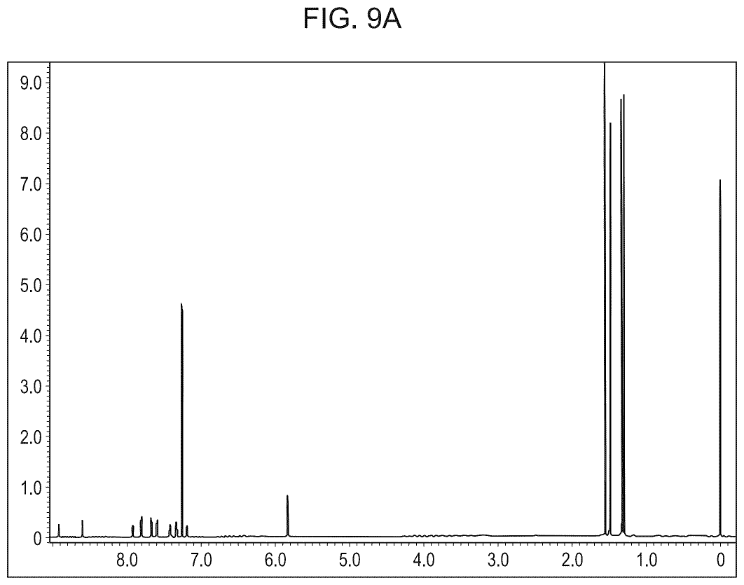

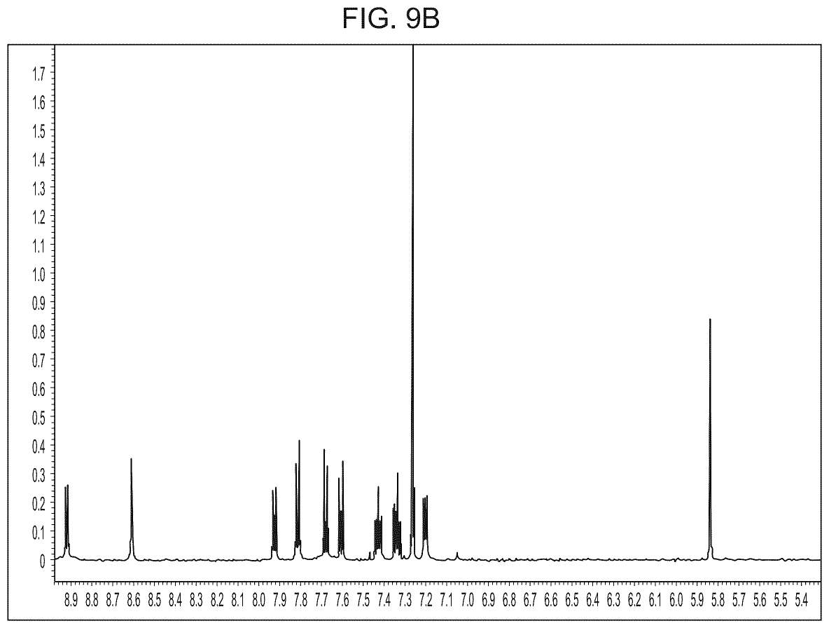

FIGS. 9A and 9B show an NMR spectrum of Example compound 03 in CDCl₃. FIG. 9A shows a range of 0 ppm to 9 ppm on the horizontal axis, and FIG. 9B shows a range of 5.4 ppm to 9 ppm on the horizontal axis. This NMR spectrum was consistent with Example compound 03, and the compound could be identified.

According to the results of the emission spectra of Example compounds 01, 02, and 04 measured as in Example compound 03, the emission peak wavelengths were 508 nm, 514 nm, and 511 nm, respectively.

### Example 2

### (1) Production of Organic EL Devices

An organic EL device A and an organic EL device B having structures below were produced. ITO/PEDOT:PSS (40 nm)/light-emitting layer (100 nm)/CsF (1 nm)/Al (250 nm)

The light-emitting layer is formed of a mixture of polyvinylcarbazole PVK, an electron transport material PBD, and Example compound 01 which is a light-emitting dopant. The mass proportions of the compounds (PVK:PBD:light-emitting dopant) were 10:3:1.7 (dopant concentration in the light-emitting layer: 13% by mass) in the organic EL device A and 10:3:0.65 (dopant concentration in the light-emitting layer: 5% by mass) in the organic EL device B.

### (2) Calculation of Emission Intensity Ratio

From EL spectra obtained at 1,000 cd/m² by applying a DC voltage to each of the organic EL elements, an emission intensity ratio between 600 nm and 520 nm (emission intensity at 600 nm/emission intensity at 520 nm) was calculated. The results are show in Table 1, where the emission intensity ratio of the organic EL device A is expressed as an emission intensity ratio A, and the emission intensity ratio of the organic EL device B is expressed as an emission intensity ratio B.

A ratio A/B (emission intensity ratio A/emission intensity ratio B) of the emission intensity ratio A to the emission intensity ratio B was calculated and evaluated on the basis of the following criteria. The results are shown in Table 1. The value of A/B is preferably less than 1.3.
a: 1.05 or less
b: more than 1.05 and less than 1.3
c: 1.3 or more

### Examples 3 to 5 and Comparative Examples 1 to 3

Organic EL devices were produced and evaluated as in Example 2 except that the light-emitting dopant was changed to the compounds described in Table 1. The results are shown in Table 1.

TABLE 1

| | | | | | | Comparative | Comparative | Comparative |
|---|---|---|---|---|---|---|---|---|
| | | Example 2 | Example 3 | Example 4 | Example 5 | Example 1 | Example 2 | Example 3 |
| | | Example | Example | Example | Example | Comparative | Comparative | Comparative |
| | | compound | compound | compound | compound | example | example | example |
| Dopant | | 01 | 02 | 03 | 04 | compound 01 | compound 02 | compound 03 |
| Emission intensity ratio A | | 0.86 | 0.82 | 0.79 | 0.80 | 1.05 | 1.07 | 1.00 |
| (Dopant concentration: | | | | | | | | |
| 13 wt %) | | | | | | | | |
| Emission intensity ratio B | | 0.80 | 0.80 | 0.76 | 0.77 | 0.74 | 0.72 | 0.75 |
| (Dopant concentration: | | | | | | | | |
| 5 wt %) | | | | | | | | |
| Emission | Ratio | 1.08 | 1.03 | 1.04 | 1.04 | 1.42 | 1.49 | 1.33 |
| intensity ratio A/ | Evaluation | b | a | a | a | c | c | c |
| Emission | | | | | | | | |
| intensity ratio B | | | | | | | | |

In Comparative Examples 1 to 3, when the light-emitting dopant concentration in the light-emitting layer is high (13% by mass), EL emission from an excimer with a peak at around 600 nm is observed on the longer wavelength side of the EL emission spectrum. As shown in Table 1, in Comparative Examples 1 to 3, the emission intensity ratio A was 1.0 or more, showing that the intensity of the excimer emission at 600 nm was higher than the intensity of an emission peak that the Pt complex originally has at around 520 nm. In contrast, in Examples 2 to 5, the emission intensity ratio A was 0.9 or less, showing that excimer emission was effectively reduced even in the case of the high dopant concentration.

On the other hand, when the light-emitting dopant concentration in the light-emitting layer is low (5% by mass), no excimer emission is observed also in Comparative Examples 1 to 3. That is, an emission spectrum that the Pt complex light-emitting dopant originally has is observed. As shown in Table 1, in Examples 2 to 5 and Comparative Examples 1 to 3, the emission intensity ratio B is 0.8 or less.

The ratio A/B of the emission intensity ratio A to the emission intensity ratio B is an indicator of deformation of the emission spectrum generated by excimer emission. A larger A/B value indicates a larger change in the emission color caused by excimer emission due to the dopant concentration. As shown in Table 1, the A/B values of Examples 2 to 5 are smaller than those of Comparative Examples 1 to 3, showing that excimer emission is effectively reduced.

As described above, it was demonstrated that, in the metal complex of the present embodiment, excimer emission was reduced even in the case of a high dopant concentration in the light-emitting layer, and the metal complex of the present embodiment was found to be a light-emitting dopant in which the dopant concentration dependence of the emission color was reduced. Accordingly, the use of the metal complex of the present embodiment as a light-emitting dopant of an organic EL device can provide an organic EL device with high emission characteristics and good productivity.

The metal complex according to the present invention achieves high productivity of an organic light-emitting device and has high emission characteristics. Therefore, an organic light-emitting device in which the metal complex according to the present invention is used in a light-emitting layer has good productivity and emission characteristics.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A metal complex represented by general formula (1): 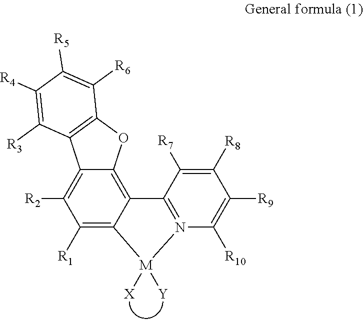
wherein M represents Pt, Pd, or Ni,
R₁ to R₁₀ are each independently selected from a hydrogen atom and an alkyl group, provided that at least one of R₁ to R₁₀ is an alkyl group having 2 or more carbon atoms, and adjacent R₁ to R₁₀ may be bonded together to form a ring, and
—X—Y— represents a bidentate ligand and is —O—O—, —N—O—, —C—N—, or —N—N—.

2. The metal complex according to claim 1, wherein M is Pt.

3. The metal complex according to claim 1, wherein at least one of R₈ and R₉ is an alkyl group having 2 or more carbon atoms.

4. The metal complex according to claim 1, wherein X—Y is an acetylacetonate derivative.

5. The metal complex according to claim 1, being represented by general formula (2): 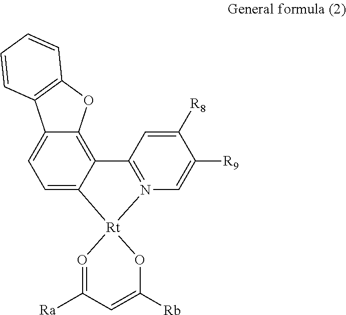
wherein Ra and Rb are each independently selected from an alkyl group and a substituted or unsubstituted aromatic ring group.

6. An organic light-emitting device comprising:
an anode;
a cathode; and
an organic compound layer disposed between the anode and the cathode,
wherein at least one layer in the organic compound layer contains the metal complex according to claim 1.

7. The organic light-emitting device according to claim 6, wherein the layer containing the metal complex is a light-emitting layer.

8. The organic light-emitting device according to claim 7, wherein the metal complex is a light-emitting dopant.

9. A display apparatus comprising:
a plurality of pixels,
wherein at least one of the plurality of pixels includes the organic light-emitting device according to claim 6 and a transistor connected to the organic light-emitting device.

10. A photoelectric conversion apparatus comprising:
an optical unit including a plurality of lenses;
an imaging device that receives light that has passed through the optical unit; and
a display unit that displays an image captured by the imaging device,
wherein the display unit includes the organic light-emitting device according to claim 6.

11. An electronic apparatus comprising:
a display unit including the organic light-emitting device according to claim 6;
a housing provided with the display unit; and
a communication unit that is disposed in the housing and communicates with an external unit.

12. An illumination apparatus comprising:
a light source including the organic light-emitting device according to claim 6; and
a light diffusion unit or an optical filter that transmits light emitted from the light source.

13. A moving object comprising:
a lighting fixture including the organic light-emitting device according to claim 6; and
a body provided with the lighting fixture.

14. An exposure light source for an electrophotographic image forming apparatus, the exposure light source comprising the organic light-emitting device according to claim 6.
